(19) United States
(12) Patent Application Publication
(10) Pub. No.: US 2024/0186956 A1
(43) Pub. Date: Jun. 6, 2024

(54) DOHERTY AMPLIFIER CIRCUIT

(71) Applicant: Murata Manufacturing Co., Ltd., Kyoto (JP)

(72) Inventor: Shohei IMAI, Kyoto (JP)

(21) Appl. No.: 18/441,291

(22) Filed: Feb. 14, 2024

Related U.S. Application Data
(63) Continuation of application No. PCT/JP2022/037884, filed on Oct. 11, 2022.

(30) Foreign Application Priority Data
Oct. 13, 2021 (JP) 2021-168430

(51) Int. Cl. H03F 1/02

(52) U.S. Cl. CPC H03F 1/0288; H03F 2200/151; H03F 2200/451

(57) ABSTRACT

A Doherty amplifier circuit includes a carrier amplifier that amplifies an input high frequency signal, a peak amplifier that amplifies an input high frequency signal, a first bias circuit that applies a bias to the carrier amplifier, a second bias circuit that applies a bias to the peak amplifier, and a control circuit that controls the second bias circuit on the basis of an input high frequency signal and a signal indicating a drive level of the carrier amplifier.

### CROSS REFERENCE TO RELATED APPLICATION

This is a continuation of International Application No. PCT/JP2022/037884 filed on Oct. 11, 2022, which claims priority from Japanese Patent Application No. 2021-168430 filed on Oct. 13, 2021. The contents of these applications are incorporated herein by reference in their entireties.

### BACKGROUND ART

### Technical Field

The present disclosure relates to a Doherty amplifier circuit.

As high-efficiency power amplifier circuits, Doherty amplifier circuits have been known. Typically, a Doherty amplifier circuit is configured such that a carrier amplifier that operates regardless of the power level of an input signal and a peak amplifier that is turned off when the power level of an input signal is small and is turned on when the power level of an input signal is large are connected in parallel. With this configuration, when the power level of a high frequency input signal is large, the carrier amplifier operates while maintaining saturation at the saturated output power level. Thus, the Doherty amplifier circuit can improve efficiency compared to normal power amplifier circuits.

Techniques for controlling the bias of a peak amplifier are described in Patent Documents 1 to 3 described below.

The technique described in Patent Document 1 is detecting saturation of a carrier amplifier by using a bias circuit for the carrier amplifier and controlling a bias circuit for a peak amplifier in accordance with a detection signal.

The technique described in Patent Document 2 is detecting saturation of a carrier amplifier on the basis of an output signal of the carrier amplifier and controlling a bias circuit for a peak amplifier in accordance with a detection signal.

The technique described in Patent Document 3 is controlling a bias circuit for a peak amplifier in accordance with the level of a high frequency input signal input to a Doherty amplifier circuit or the level of a high frequency input signal input to a carrier amplifier.
Patent Document 1: U.S. Patent Application Publication No. 2016/0241209
Patent Document 2: U.S. Patent Application Publication No. 2020/0028472
Patent Document 3: Japanese Unexamined Patent Application Publication No. 2019-41277

### BRIEF SUMMARY

In the techniques described in Patent Documents 1 and 2, it takes about several tens of nanoseconds for a circuit that detects saturation of a carrier amplifier to respond. Thus, inconvenience described below may occur. For example, in the case where a high frequency input signal with a momentary (much shorter than several tens of nanoseconds) increase in power is input to a Doherty amplifier circuit, a time during which the carrier amplifier saturates may occur during the duration of several tens of nanoseconds from the start of saturation of the carrier amplifier to a change of a bias point of the peak amplifier. Thus, the quality of a high frequency output signal of the Doherty amplifier circuit cannot always be maintained high. Furthermore, in the case where the Doherty amplifier circuit is applied to a communication apparatus, the quality of communication cannot always be maintained high.

In the technique described in Patent Document 3, although operation is performed in accordance with the level of a high frequency input signal, since the level of the high frequency input signal is detected by the bias circuit, the response speed is basically considered to be low. Thus, the quality of a high frequency output signal of the Doherty amplifier circuit cannot always be maintained high.

The present disclosure suppresses a decrease in the quality of a high frequency output signal.

A Doherty amplifier circuit according to an aspect of the present disclosure includes a carrier amplifier that amplifies an input high frequency signal, a peak amplifier that amplifies an input high frequency signal, a first bias circuit that applies a bias to the carrier amplifier, a second bias circuit that applies a bias to the peak amplifier, and a control circuit that controls the second bias circuit on the basis of an input high frequency signal and a signal indicating a drive level of the carrier amplifier.

According to the present disclosure, a decrease in the quality of a high frequency output signal can be suppressed.

### BRIEF DESCRIPTION OF THE DRAWINGS

FIG. 1 is a diagram illustrating a configuration of a power amplifier circuit according to a first embodiment.

FIG. 2 is a schematic diagram illustrating an example of the relationship between power of a high frequency signal in the power amplifier circuit according to the first embodiment and a signal output from a detection circuit.

FIG. 3 is a diagram illustrating a configuration of the detection circuit of the power amplifier circuit according to the first embodiment.

FIG. 4 is a diagram illustrating an example of the relationship between power of a high frequency signal in the power amplifier circuit according to the first embodiment and a bias voltage applied to a peak amplifier.

FIG. 5 is a diagram illustrating a specific example of a bias circuit that applies a bias to a final-stage carrier amplifier and the detection circuit in the power amplifier circuit according to the first embodiment.

FIG. 6 is a diagram illustrating a configuration of a power amplifier circuit according to a first modification of the first embodiment.

FIG. 7 is a diagram illustrating a configuration of a power amplifier circuit according to a second modification of the first embodiment.

FIG. 8 is a diagram illustrating a configuration of a power amplifier circuit according to a second embodiment.

FIG. 9 is a diagram illustrating a specific example of a detection circuit and a variable attenuator in the power amplifier circuit according to the second embodiment.

FIG. 10 is a diagram illustrating a configuration of a power amplifier circuit according to a third embodiment.

FIG. 11 is a diagram illustrating a configuration of a power amplifier circuit according to a fourth embodiment.

FIG. 12 is a diagram illustrating a specific example of a detection circuit and an adder circuit in the power amplifier circuit according to the fourth embodiment.

FIG. 13 is a diagram illustrating a configuration of a power amplifier circuit according to a fifth embodiment.

FIG. 14 is a diagram illustrating a specific example of a detection circuit and a drive level detection circuit in the power amplifier circuit according to the fifth embodiment.

FIG. 15 is a diagram illustrating an equivalent circuit of a specific example of the detection circuit and the drive level detection circuit in the power amplifier circuit according to the fifth embodiment.

FIG. 16 is a diagram illustrating a configuration of a power amplifier circuit according to a sixth embodiment.

FIG. 17 is a diagram illustrating a configuration of a power amplifier circuit according to a seventh embodiment.

FIG. 18 is a diagram illustrating a configuration of a power amplifier circuit according to an eighth embodiment.

FIG. 19 is a diagram illustrating a configuration of a power amplifier circuit according to a ninth embodiment.

### DETAILED DESCRIPTION

Hereinafter, Doherty amplifier circuits according to embodiments of the present disclosure will be described in detail with reference to drawings. The embodiments are not intended to limit the present disclosure. Each of the embodiments is illustrative and, obviously, components illustrated in different embodiments can be partially replaced or combined. In second and subsequent embodiments, description of matters common to a first embodiment will be omitted, and only different points will be described. In particular, similar operational effects obtained by similar configurations will not be repeatedly described in each embodiment.

### First Embodiment

### (Entire Configuration)

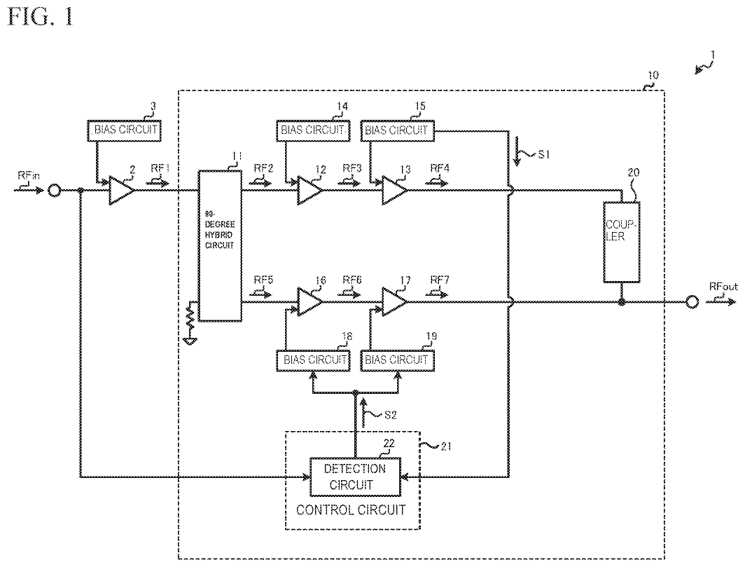

FIG. 1 is a diagram illustrating a configuration of a power amplifier circuit according to the first embodiment. A power amplifier circuit 1 includes an amplifier 2, a bias circuit 3, and a Doherty amplifier circuit 10. The Doherty amplifier circuit 10 includes a 90-degree hybrid circuit 11, an initial-stage (driver-stage) carrier amplifier 12, a final-stage (power-stage) carrier amplifier 13, bias circuits 14 and 15, an initial-stage peak amplifier 16, a final-stage peak amplifier 17, bias circuits 18 and 19, a coupler 20, and a control circuit 21. The control circuit 21 includes a detection circuit 22.

Each of the bias circuits 14 and 15 corresponds to an example of a “first bias circuit” according to the present disclosure. Each of the bias circuits 18 and 19 corresponds to a “second bias circuit” according to the present disclosure.

The number of stages of the Doherty amplifier circuit 10 is two. However, the present disclosure is not limited to this example. The number of stages of the Doherty amplifier circuit 10 may be one or three or more.

The bias circuit 3 applies a bias to the amplifier 2. The amplifier 2 outputs a high frequency signal RF1 obtained by amplifying a high frequency signal RFin to the 90-degree hybrid circuit 11. The 90-degree hybrid circuit 11 divides the high frequency signal RF1 into high frequency signals RF2 and RF5 whose phases are different by approximately 90 degrees, outputs the high frequency signal RF2 to the carrier amplifier 12, and outputs the high frequency signal RF5 to the peak amplifier 16. “Approximately 90 degrees” not only represents a phase of 90 degrees but also includes a phase of 90 degrees plus/minus 45 degrees.

The phase of the high frequency signal RF5 is illustrated as being delayed by 90 degrees with respect to the high frequency signal RF2. The power of the high frequency signal RF2 and the power of the high frequency signal RF5 are illustrated as being the same.

The bias circuit 14 applies a bias to the carrier amplifier 12. The bias circuit 15 applies a bias to the carrier amplifier 13. The carrier amplifier 12 outputs a high frequency signal RF3 obtained by amplifying the high frequency signal RF2 to the carrier amplifier 13. The carrier amplifier 13 outputs a high frequency signal RF4 obtained by amplifying the high frequency signal RF3 to the coupler 20.

The bias circuit 18 applies a bias to the peak amplifier 16. The bias circuit 19 applies a bias to the peak amplifier 17. The peak amplifier 16 outputs a high frequency signal RF6 obtained by amplifying the high frequency signal RF5 to the peak amplifier 17. The peak amplifier 17 outputs a high frequency signal RF7 obtained by amplifying the high frequency signal RF6 to the coupler 20.

The coupler 20 couples the high frequency signal RF4 with the high frequency signal RF7. In the first embodiment, the coupler 20 is a phase shifter. However, the present disclosure is not limited to this example. The coupler 20 performs output in such a manner that the phase of the high frequency signal RF4 is delayed by 90 degrees. The sum of the high frequency signal RF7 and the output signal of the coupler 20 is a high frequency signal RFout.

The high frequency signal RFin and a signal S1 indicating the drive level (operation level) of the carrier amplifier 13 are input to the detection circuit 22. Instead of the high frequency signal RFin, the high frequency signal RF1 may be input to the detection circuit 22. The signal S1 may be output from the bias circuit 15 or may be output from the carrier amplifier 13. In the case where the signal S1 is output from the carrier amplifier 13, the signal S1 may be the high frequency signal RF4. The signal S1 may be a signal (inversion signal) that changes in a complementary manner according to the drive level of the carrier amplifier 13.

The detection circuit 22 outputs a signal S2 for controlling the bias circuits 18 and 19 to the bias circuits 18 and 19 on the basis of the high frequency signal RFin and the signal S1. The bias circuit 18 applies a bias to the peak amplifier 16 on the basis of the signal S2. The bias circuit 19 applies a bias to the peak amplifier 17 on the basis of the signal S2.

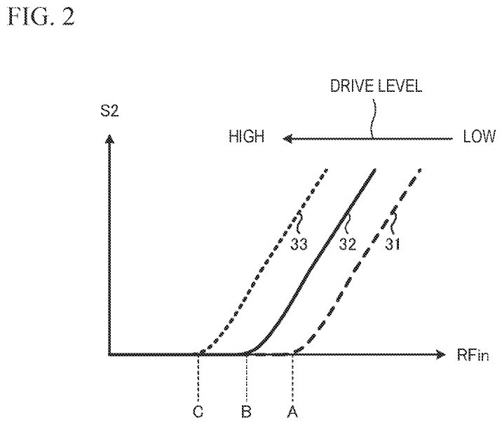

FIG. 2 is a schematic diagram illustrating an example of the relationship between power of a high frequency signal in the power amplifier circuit according to the first embodiment and a signal output from the detection circuit. In FIG. 2, the horizontal axis represents power of the high frequency signal RFin, and the vertical axis represents the signal S2 output from the detection circuit 22.

The detection circuit 22 changes the rising point of the signal S2 in accordance with the signal S1. A waveform 31 represents the relationship between the power of the high frequency signal RFin and the signal S2 in the case where the drive level of the carrier amplifier 13 is relatively low. A waveform 32 represents the relationship between the power of the high frequency signal RFin and the signal S2 in the case where the drive level of the carrier amplifier 13 is relatively medium. A waveform 33 represents the relationship between the power of the high frequency signal RFin and the signal S2 in the case where the drive level of the carrier amplifier 13 is relatively high.

In the case where the drive level of the carrier amplifier 13 is relatively low, when the power of the high frequency signal RFin reaches a value A, the detection circuit 22 causes the signal S2 to rise, as indicated by the waveform 31. In the case where the power of the high frequency signal RFin is equal to or more than the value A, the detection circuit 22 increases the signal S2 as the power of the high frequency signal RFin increases.

In the case where the drive level of the carrier amplifier 13 is relatively medium, when the power of the high frequency signal RFin reaches a value B (B<A), the detection circuit 22 causes the signal S2 to rise, as indicated by the waveform 32. In the case where the power of the high frequency signal RFin is equal to or more than the value B, the detection circuit 22 increases the signal S2 as the power of the high frequency signal RFin increases.

In the case where the drive level of the carrier amplifier 13 is relatively high, when the power of the high frequency signal RFin reaches a value C (C<B), the detection circuit 22 causes the signal S2 to rise, as indicated by the waveform 33. In the case where the power of the high frequency signal RFin is equal to or more than the value C, the detection circuit 22 increases the signal S2 as the high frequency signal RFin increases.

In the case where input of a high frequency signal RFin with a high power, which is a main cause of saturation of the carrier amplifiers 12 and 13, occurs, the detection circuit 22 outputs the signal S2 to the bias circuits 18 and 19, so that the bias circuits 18 and 19 activate the peak amplifiers 16 and 17. Thus, basically, the carrier amplifiers 12 and 13 do not saturate.

Improving the response speed of the detection circuit 22 is suitable. Since the detection circuit 22 detects the high frequency signal RFin, the detection circuit 22 can respond at a significantly high speed, compared to the techniques in Patent Documents 1 and 2 in which saturation of a carrier amplifier is detected. Thus, even in the case where the power of the high frequency signal RFin has increased in a short period of time, the detection circuit 22 quickly responds and causes the bias circuits 18 and 19 to activate the peak amplifiers 16 and 17. Therefore, saturation of the carrier amplifiers 12 and 13 does not occur even for a moment.

However, in the case where temperature or other surrounding environmental conditions change (for example, in the case where the gain of the carrier amplifiers 12 and 13 increases at an extremely low temperature), the carrier amplifiers 12 and 13 may saturate even when the power of the high frequency signal RFin is low. To cope with such a case, the detection circuit 22 detects the signal S1 indicating the drive level of the carrier amplifiers 12 and 13. In the case where the carrier amplifiers 12 and 13 are in a state close to saturation, the detection circuit 22 promptly activates the peak amplifiers 16 and 17 even if the power of the high frequency signal RFin is low.

Since the detection circuit 22 detects the high frequency signal RFin, even if it takes time to detect the drive level of the carrier amplifiers 12 and 13, the detection circuit 22 is able to cause the bias circuits 18 and 19 to activate the peak amplifiers 16 and 17 without necessarily causing the carrier amplifiers 12 and 13 to saturate. Thus, the Doherty amplifier circuit 10 can suppress a decrease in the quality of the high frequency signal RFout.

It can be considered that the detection circuit 22 operates in a feed-forward manner in accordance with the high frequency signal RFin and operates in a feed-back manner in accordance with the signal S1.

### (Configuration of Detection Circuit)

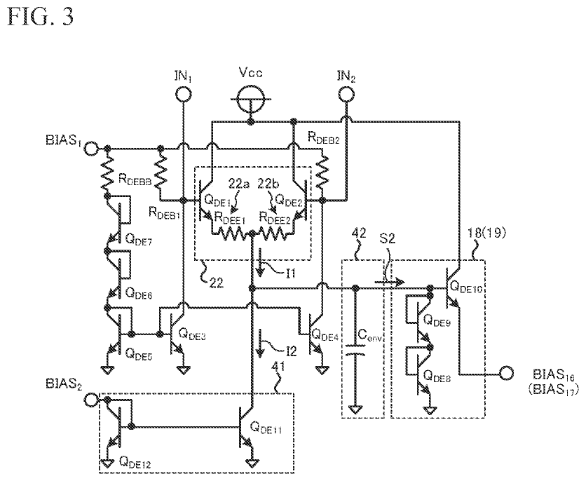

FIG. 3 is a diagram illustrating a configuration of the detection circuit of the power amplifier circuit according to the first embodiment. In FIG. 3, circuit elements for applying bias to the detection circuit 22 are also illustrated. A low pass filter 42 and the bias circuits 18 and 19 illustrated in FIG. 3 may be omitted. In the case where excellent differential signals can be obtained or other cases, the low pass filter 42 may be omitted. In the case where bias supply target transistors (amplifier transistors) are small or other cases, the bias circuits 18 and 19 may be omitted.

The detection circuit 22 includes transistors Q_{DE1} and Q_{DE2} and resistors R_{DEE1} and R_{DEE2}.

In the present disclosure, each of the transistors is a bipolar transistor. However, the present disclosure is not limited to this example. As the bipolar transistor, a heterojunction bipolar transistor (HBT) is illustrated. However, the present disclosure is not limited to this example. The transistor may be, for example, a field effect transistor (FET). The transistor may be a multi-finger transistor including a plurality of unit transistors that are electrically connected in parallel. A unit transistor represents the minimum element of a transistor.

The collector of the transistor Q_{DE1} is electrically connected to a power supply potential Vcc. The emitter of the transistor Q_{DE1} is electrically connected to one end of the resistor R_{DEE1}. That is, the transistor Q_{DE1} and the resistor R_{DEE1} are emitter-follower connected. The transistor Q_{DE1} and the resistor R_{DEE1} form a first emitter-follower circuit 22a.

The detection circuit 22 may include a source-follower circuit, instead of the first emitter-follower circuit 22a.

The collector of the transistor Q_{DE2} is electrically connected to the power supply potential Vcc. The emitter of the transistor Q_{DE2} is electrically connected to one end of the resistor R_{DEE2}. That is, the transistor Q_{DE2} and the resistor R_{DEE2} are emitter-follower connected. The transistor Q_{DE2} and the resistor R_{DEE2} form a second emitter-follower circuit 22b.

The detection circuit 22 may include a source-follower circuit, instead of the second emitter-follower circuit 22b.

The other end of the resistor R_{DEE1} and the other end of the resistor R_{DEE2} are electrically connected. The sum of an output current of the first emitter-follower circuit 22a and an output current of the second emitter-follower circuit 22b is an output current I1 of the detection circuit 22.

Resistors R_{DEBB}, R_{DEB1}, and R_{DEB2} and transistors Q_{DE5}, Q_{DE6}, and Q_{DE7} apply bias voltages to the bases of the transistors Q_{DE1} and Q_{DE2}.

One end of the resistor R_{DEBB}, one end of the resistor R_{DEB1}, and one end of the resistor R_{DEB2} are electrically connected.

The other end of the resistor R_{DEBB} is electrically connected to the collector and base of the transistor Q_{DE7}. That is, the transistor Q_{DE7} is diode-connected. The emitter of the transistor Q_{DE7} is electrically connected to the collector and base of the transistor Q_{DE6}. That is, the transistor Q_{DE6} is diode-connected. The emitter of the transistor Q_{DE6} is electrically connected to the collector and base of the transistor Q_{DE5}. That is, the transistor Q_{DE5} is diode-connected. The emitter of the transistor Q_{DE5} is electrically connected to a reference potential. The reference potential is illustrated as a ground potential. However, the present disclosure is not limited to this example.

A bias current BIAS₁ is input to one end of the resistor R_{DEBB}, one end of the resistor R_{DEB1}, and one end of the resistor R_{DEB2}. The resistor R_{DEBB}, the transistor Q_{DE7}, the transistor Q_{DE6}, and the transistor Q_{DE5} generate a constant voltage. This voltage is input to the base of the transistor Q_{DE1} through the resistor R_{DEB1} and to the base of the transistor Q_{DE2} through the resistor R_{DEB2}.

Each of the transistors Q_{DE3} and Q_{DE4} is current-mirror connected to the transistor Q_{DE5}. The collector of the transistor Q_{DE3} is electrically connected to the base of the transistor Q_{DE1}. Thus, the transistor Q_{DE3} is capable of adjusting the base current of the transistor Q_{DE1}. The collector of the transistor Q_{DE4} is electrically connected to the base of the transistor Q_{DE2}. Thus, the transistor Q_{DE4} is capable of adjusting the base current of the transistor Q_{DE2}.

High frequency signals IN₁ and IN₂ obtained by converting the high frequency signal RFin into differential signals are input to the base of the transistor Q_{DE1} and the base of the transistor Q_{DE2}, respectively. The high frequency signals IN₁ and IN₂ can be obtained by, for example, inputting the high frequency signal RFin to a balun.

The other end of the resistor R_{DEE1} and the other end of the resistor R_{DEE2} are electrically connected to a constant current circuit 41. The constant current circuit 41 includes transistors Q_{DE11} and Q_{DE12}. The constant current circuit 41 is a current bias circuit for the detection circuit 22.

The transistor Q_{DE12} is diode-connected. A voltage BIAS₂ indicating the drive level of the carrier amplifier 13 (see FIG. 1) is input to the collector and base of the transistor Q_{DE12}.

In the first embodiment, the voltage BIAS₂ is a voltage that changes in a complementary manner according to the drive level of the carrier amplifier 13. In the case where the drive level of the carrier amplifier 13 is relatively high (close to saturation), the voltage BIAS₂ is relatively low. In the case where the drive level of the carrier amplifier 13 is relatively low (amplification rate decreases), the voltage BIAS₂ is relatively high.

The transistor Q_{DE11} is current-mirror connected to the transistor Q_{DE12}. Thus, a collector current I2 of the transistor Q_{DE11} is a current corresponding to the voltage BIAS₂.

The collector of the transistor Q_{DE11} is electrically connected to the other end of the resistor R_{DEE1} and the other end of the resistor R_{DEE2}.

The low pass filter 42 includes a capacitor Cₑₙᵥ. One end of the capacitor Cₑₙᵥ is electrically connected to the other end of the resistor R_{DEE1}, the other end of the resistor R_{DEE2}, and the collector of the transistor Q_{DE11}. The other end of the capacitor Cₑₙᵥ is electrically connected to the reference potential.

The capacitor Cₑₙᵥ is charged or discharged in accordance with a difference between the output current I1 of the detection circuit 22 and the collector current I2 of the transistor Q_{DE11}. The voltage of the capacitor Cₑₙᵥ serves as the signal S2. The capacitor Cₑₙᵥ terminates a high frequency component (for example, a carrier frequency signal component) of the signal S2 to the reference potential and eliminates the high frequency component, so that only a low frequency component passes through the capacitor Cₑₙᵥ. Thus, the capacitor Cₑₙᵥ allows the bias circuits 18 and 19 in the stage following the low pass filter 42 and a bias supply target transistor (amplifier transistor) to be properly biased.

The bias circuit 18 includes transistors Q_{DE8}, Q_{DE9}, and Q_{DE10}. Since the circuit configuration of the bias circuit 19 (see FIG. 1) is similar to the circuit configuration of the bias circuit 18, description of the circuit configuration of the bias circuit 19 will be omitted.

The transistor Q_{DE9} is diode-connected. The collector and base of the transistor Q_{DE9} are electrically connected to one end of the capacitor Cₑₙᵥ. The emitter of the transistor Q_{DE9} is electrically connected to the collector and base of the transistor Q_{DE8}. The transistor Q_{DE8} is diode-connected. The emitter of the transistor Q_{DE8} is electrically connected to the reference potential. A current corresponding to the voltage of the capacitor Cₑₙᵥ flows to the transistors Q_{DE9} and Q_{DE8}.

The collector of the transistor Q_{DE10} is electrically connected to the power supply potential Vcc. The base of the transistor Q_{DE10} is electrically connected to the collector and base of the transistor Q_{DE9}. The emitter voltage of the transistor Q_{DE10} is output as a bias voltage BIAS₁₆ (BIAS₁₇) to the peak amplifier 16 (17).

Operation of the detection circuit 22 will be described.

The transistor Q_{DE1} is turned on when the high frequency signal IN₁ is equal to or more than a threshold voltage of the transistor Q_{DE1}, and outputs an emitter current. The transistor Q_{DE2} is turned on when the high frequency signal IN₂ is equal to or more than a threshold voltage of the transistor Q_{DE2}, and outputs an emitter current.

That is, as the amplitudes of the high frequency signals IN₁ and IN₂ increase (power of the high frequency signal RFin increases), the output current of the detection circuit 22 increases. Furthermore, as the amplitudes of the high frequency signals IN₁ and IN₂ decrease (power of the high frequency signal RFin decreases), the output current of the detection circuit 22 decreases.

In contrast, as described above, the voltage BIAS₂ is relatively low in the case where the drive level of the carrier amplifier 13 is relatively high (close to saturation), and the voltage BIAS₂ is relatively high in the case where the drive level of the carrier amplifier 13 is relatively low (amplification rate decreases).

That is, as the drive level of the carrier amplifier 13 relatively increases (closer to saturation), the collector current I2 of the transistor Q_{DE11} decreases. Furthermore, as the drive level of the carrier amplifier 13 relatively decreases (amplification rate decreases), the collector current I2 of the transistor Q_{DE11} increases.

Summarizing the above, the voltage of the capacitor Cₑₙᵥ is more likely to increase as the drive level of the carrier amplifier 13 relatively increases (closer to saturation). The voltage of the capacitor Cₑₙᵥ is less likely to increase as the drive level of the carrier amplifier 13 relatively decreases (amplification rate decreases). Furthermore, the voltage of the capacitor Cₑₙᵥ is more likely to increase as the power of the high frequency signal RFin increases. The voltage of the capacitor Cₑₙᵥ is less likely to increase as the power of the high frequency signal RFin decreases.

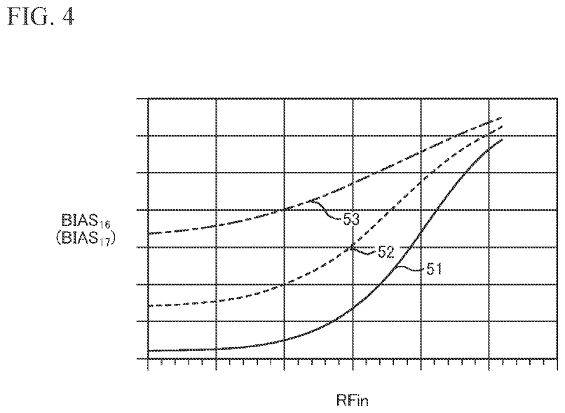

FIG. 4 is a diagram illustrating an example of the relationship between power of a high frequency signal in the power amplifier circuit according to the first embodiment and a bias voltage applied to a peak amplifier. In FIG. 4, the horizontal axis represents the power of the high frequency signal RFin, and the vertical axis represents the bias voltage BIAS₁₆ (BIAS₁₇) applied to the peak amplifier 16 (17) from the bias circuit 18 (19).

A waveform 51 represents variations in the bias voltage BIAS₁₆ (BIAS₁₇) in the case where the drive level of the carrier amplifier 13 is relatively low. A waveform 52 represents variations in the bias voltage BIAS₁₆ (BIAS₁₇) in the case where the drive level of the carrier amplifier 13 is relatively medium. A waveform 53 represents variations in the bias voltage BIAS₁₆ (BIAS₁₇) in the case where the drive level of the carrier amplifier 13 is relatively high.

In the case where the drive level of the carrier amplifier 13 is relatively high, the detection circuit 22 is able to cause the peak amplifiers 16 and 17 to rise even when the power of the high frequency signal RFin is low, as indicated by the waveform 53. In contrast, in the case where the drive level of the carrier amplifier 13 is relatively low, the detection circuit 22 is able to delay the rise of the peak amplifiers 16 and 17 until the power of the high frequency signal RFin becomes high, as indicated by the waveform 51.

Thus, in the case where the drive level of the carrier amplifier 13 is relatively high (close to saturation), the current of the constant current circuit 41 may be small so that the peak amplifiers 16 and 17 can be caused to rise even when the power of the high frequency signal RFin is low. In contrast, in the case where the drive level of the carrier amplifier 13 is relatively low, since there is no need to rise the peak amplifiers 16 and 17 until the power of the high frequency signal RFin becomes high, the current of the constant current circuit 41 may be large. That is, by setting the voltage BIAS₂ input to the constant current circuit 41 to be a voltage that changes in a complementary manner according to the drive level of the carrier amplifier 13, a desired operation as the entire circuit can be attained.

Rapid response of the detection circuit 22 can be achieved due to the reasons described below.

Firstly, differential operation is performed by the first emitter-follower circuit 22a and the second emitter-follower circuit 22b. Thus, compared to the case where an emitter-follower circuit performs a single-end operation, the capacitance of the capacitor Cₑₙᵥ can be decreased. Accordingly, delay at the capacitor Cₑₙᵥ can be reduced, and the signal S2 quickly changes. That is, the detection circuit 22 can respond quickly.

Secondly, an emitter-follower circuit is a circuit capable of outputting a large current. Therefore, each of the first emitter-follower circuit 22a and the second emitter-follower circuit 22b is capable of outputting a large current. That is, the detection circuit 22 is capable of outputting a large output current I1. Thus, the detection circuit 22 is capable of charging the capacitor Cₑₙᵥ quickly. That is, the rise response of the detection circuit 22 is fast.

Thirdly, the transistor Q_{DE11} is capable of discharging the capacitor Cₑₙᵥ using a constant current (collector current I2). Thus, the transistor Q_{DE11} is capable of discharging the capacitor Cₑₙᵥ quickly. That is, the drop response of the detection circuit 22 is fast.

### Specific Example of Bias Circuit and Detection Circuit

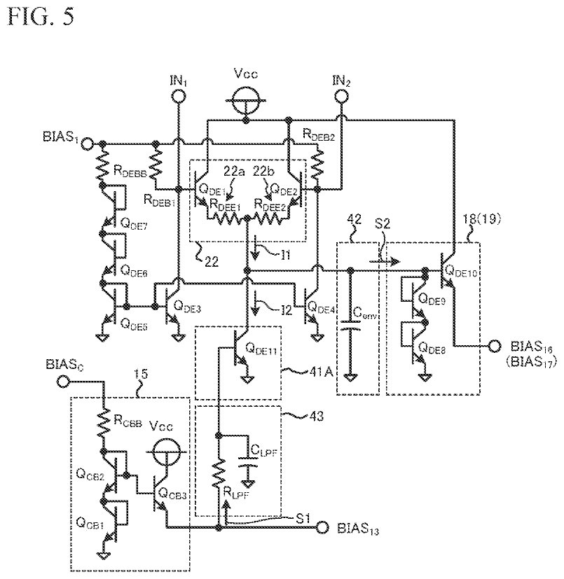

FIG. 5 is a diagram illustrating a specific example of a bias circuit that applies a bias to the final-stage carrier amplifier and the detection circuit in the power amplifier circuit according to the first embodiment.

The bias circuit 15 that applies a bias to the final-stage carrier amplifier 13 includes a resistor R_{CBB} and transistors Q_{CB1}, Q_{CB2}, and Q_{CB3}.

A bias current BIAS_{C} is input to one end of the resistor R_{CBB}. The other end of the resistor R_{CBB} is connected to the transistors Q_{CB1} and Q_{CB2}. The transistors Q_{CB1} and Q_{CB2} are circuits in which base and collector terminals of the transistors are connected so as to operate similarly to diodes and are connected in a two-stage manner. The base of the transistor Q_{CB3} is electrically connected to the base of the transistor Q_{CB2}. The collector of the transistor Q_{CB3} is electrically connected to the power supply potential Vcc. The transistor Q_{CB3} outputs, through the emitter thereof, a bias current BIAS₁₃ to the carrier amplifier 13.

In this specific example, the emitter voltage of the transistor Q_{CB3} corresponds to the signal S1.

A low pass filter 43 includes a resistor R_{LPF} and a capacitor C_{LPF}.

One end of the resistor R_{LPF} is electrically connected to the emitter of the transistor Q_{CB3}. The other end of the resistor R_{LPF} is electrically connected to one end of the capacitor C_{LPF}. The other end of the capacitor C_{LPF} is electrically connected to the reference potential.

Unlike the constant current circuit 41 (see FIG. 3), a constant current circuit 41A does not include the transistor Q_{DE12}. However, the present disclosure is not limited to this example. In this specific example, instead of the constant current circuit 41A, the constant current circuit 41 may be provided.

The other end of the resistor R_{LPF} and the one end of the capacitor C_{LPF} are electrically connected to the base of the transistor Q_{DE11}. The low pass filter 43 performs low-pass filtering of the signal S1 and outputs the low-pass filtered signal S1 to the base of the transistor Q_{DE11}.

In the circuit illustrated in FIG. 5, the principle that the output terminal voltage of the bias circuit 15 (the emitter voltage of the transistor Q_{CB3}, the signal S1) decreases in the case where the drive level of the carrier amplifier 13 is high is used. That is, the signal S1 is a signal that changes in a complementary manner according to the drive level of the carrier amplifier 13. The transistor Q_{DE11} converts the signal S1 from voltage to current (collector current I2), and the converted current is used as the current bias of the detection circuit 22. As described above, the detection circuit 22 detects the drive level of the carrier amplifier 13 on the basis of the signal S1, and controls the bias circuit 18 (19).

Furthermore, in the circuit illustrated in FIG. 5, the low pass filter 43 is provided at a path from the output terminal of the bias circuit 15 (the emitter of the transistor Q_{CB3}) to the detection circuit 22. In Patent Documents 1 to 3, inserting a low pass filter into a circuit is not desirable because the response speed of the circuit decreases.

In contrast, in the circuit illustrated in FIG. 5, improving the response speed of a path from the base of the transistors Q_{DE1} and Q_{DE2} to which the high frequency signals IN₁ and IN₂ are input to the bias circuit 18 (19) is suitable. However, occurrence of a slight delay (for example, a delay of a few seconds) in the path from the output terminal of the bias circuit 15 (the emitter of the transistor Q_{CB3}) to the detection circuit 22 is not an issue. Therefore, the low pass filter 43 can be provided at the path.

Thus, at the path connecting the bias circuit 15, the detection circuit 22, the bias circuit 19, the peak amplifier 17, the coupler 20, the carrier amplifier 13, and the bias circuit 15 in that order, isolation in a high frequency signal band can be increased. If isolation in the path is not sufficient, the path may become a return path, which may cause oscillation. However, in the circuit illustrated in FIG. 5, provision of the low pass filter 43 may suppress oscillation.

In the case where the peak bias circuit has three or more stages, the control circuit 21 may control at least the bias circuit 18 that applies a bias to the initial-stage peak amplifier 16 and the bias circuit 19 that applies a bias to the final-stage peak amplifier 17.

### First Modification

In the first embodiment, the amplifier 2 in the stage preceding the Doherty amplifier circuit 10 is a single-end amplifier. However, the present disclosure is not limited to this example. An amplifier in the stage preceding the Doherty amplifier circuit 10 may be a differential amplifier.

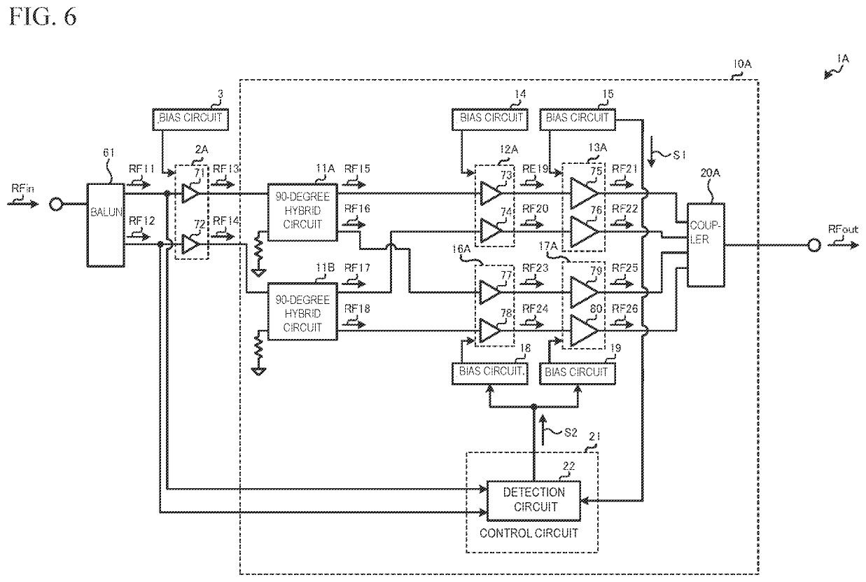

FIG. 6 is a diagram illustrating a configuration of a power amplifier circuit according to a first modification of the first embodiment.

A power amplifier circuit 1A includes a balun 61, an amplifier 2A, the bias circuit 3, and a Doherty amplifier circuit 10A. The Doherty amplifier circuit 10A includes 90-degree hybrid circuits 11A and 11B, an initial-stage carrier amplifier 12A, a final-stage carrier amplifier 13A, the bias circuits 14 and 15, an initial-stage peak amplifier 16A, a final-stage peak amplifier 17A, the bias circuits 18 and 19, a coupler 20A, and the control circuit 21.

The number of stages of the Doherty amplifier circuit 10A is two. However, the present disclosure is not limited to this example. The number of stages of the power amplifier circuit 10A may be one or three or more.

Each of the amplifier 2A, the carrier amplifiers 12A and 13A, and the peak amplifiers 16A and 17A is a differential amplifier.

In the present disclosure, it is desirable that the difference of voltage amplitude between an output signal of one amplifier in the differential amplifier and an output signal of the other amplifier in the differential amplifier be 3 dB or less and the phase difference be within a range from 90 degrees to 270 degrees.

The balun 61 outputs high frequency signals RF11 and RF12 that form differential signals, on the basis of the input high frequency signal RFin.

The bias circuit 3 applies a bias to the amplifier 2A. A first amplifier 71 in the amplifier 2A outputs a high frequency signal RF13 obtained by amplifying the high frequency signal RF11 to the 90-degree hybrid circuit 11A. A second amplifier 72 outputs a high frequency signal RF14 obtained by amplifying the high frequency signal RF12 to the 90-degree hybrid circuit 11B.

The 90-degree hybrid circuit 11A divides the high frequency signal RF13 into high frequency signals RF15 and RF16 whose phases are different by approximately 90 degrees. The 90-degree hybrid circuit 11A outputs the high frequency signal RF15 to the carrier amplifier 12A, and outputs the high frequency signal RF16 to the peak amplifier 16A.

The 90-degree hybrid circuit 11B divides the high frequency signal RF14 into high frequency signals RF17 and RF18 whose phases are different by approximately 90 degrees. The 90-degree hybrid circuit 11B outputs the high frequency signal RF17 to the carrier amplifier 12A, and outputs the high frequency signal RF18 to the peak amplifier 16A.

The bias circuit 14 applies a bias to the carrier amplifier 12A. A first amplifier 73 in the carrier amplifier 12A outputs a high frequency signal RF19 obtained by amplifying the high frequency signal RF15 to the carrier amplifier 13A. A second amplifier 74 in the carrier amplifier 12A outputs a high frequency signal RF20 obtained by amplifying the high frequency signal RF17 to the carrier amplifier 13A.

The bias circuit 15 applies a bias to the carrier amplifier 13A. A first amplifier 75 in the carrier amplifier 13A outputs a high frequency signal RF21 obtained by amplifying the high frequency signal RF19 to the coupler 20A. A second amplifier 76 in the carrier amplifier 13A outputs a high frequency signal RF22 obtained by amplifying the high frequency signal RF20 to the coupler 20A.

The bias circuit 18 applies a bias to the peak amplifier 16A. A first amplifier 77 in the peak amplifier 16A outputs a high frequency signal RF23 obtained by amplifying the high frequency signal RF16 to the peak amplifier 17A. A second amplifier 78 in the peak amplifier 16A outputs a high frequency signal RF24 obtained by amplifying the high frequency signal RF18 to the peak amplifier 17A.

The bias circuit 19 applies a bias to the peak amplifier 17A. A first amplifier 79 in the peak amplifier 17A outputs a high frequency signal RF25 obtained by amplifying the high frequency signal RF23 to the coupler 20A. A second amplifier 80 in the peak amplifier 17A outputs a high frequency signal RF26 obtained by amplifying the high frequency signal RF24 to the coupler 20A.

The coupler 20A couples the high frequency signals RF21, RF22, RF25, and RF26, and outputs the high frequency signal RFout.

The high frequency signals RF11 and RF12 and the signal S1 indicating the drive level of the carrier amplifier 13A are input to the detection circuit 22.

In the first modification, the high frequency signals RF11 and RF12 correspond to the high frequency signals IN₁ and IN₂ (see FIG. 3).

Instead of the high frequency signals RF11 and RF12, the high frequency signals RF13 and RF14 may be input to the detection circuit 22. The signal S1 may be output from the bias circuit 15 or may be output from the carrier amplifier 13A.

The detection circuit 22 outputs the signal S2 to the bias circuits 18 and 19 on the basis of the high frequency signals RF11 and RF12 and the signal S1. The bias circuit 18 applies a bias to the peak amplifier 16A on the basis of the signal S2. The bias circuit 19 applies a bias to the peak amplifier 17A on the basis of the signal S2.

### Second Modification

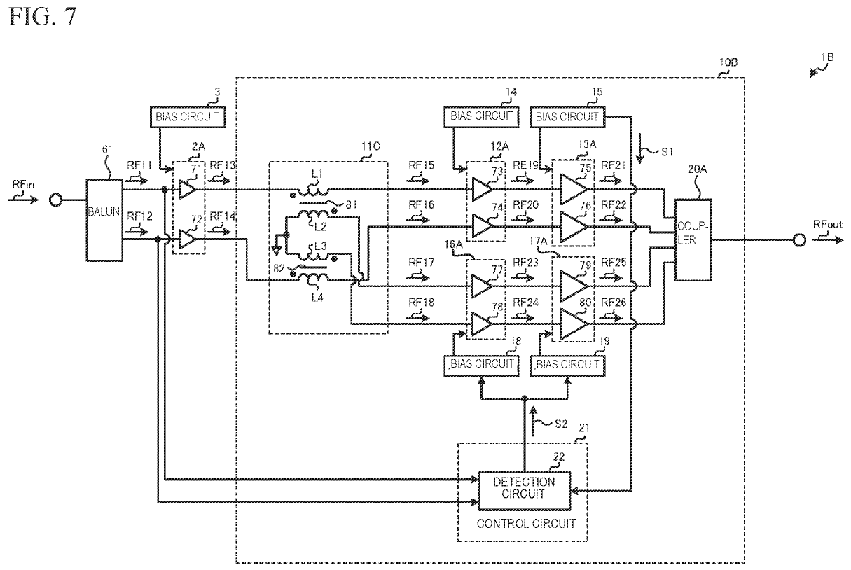

FIG. 7 is a diagram illustrating a configuration of a power amplifier circuit according to a second modification of the first embodiment.

Unlike the power amplifier circuit 1A according to the first modification (see FIG. 6), a power amplifier circuit 1B includes a Doherty amplifier circuit 10B, instead of the Doherty amplifier circuit 10A. The Doherty amplifier circuit 10B includes a 90-degree hybrid circuit 11C, instead of the 90-degree hybrid circuits 11A and 11B.

The number of stages of the Doherty amplifier circuit 10B is two. However, the present disclosure is not limited to this example. The number of stages of the Doherty amplifier circuit 10B may be one or three or more.

The 90-degree hybrid circuit 11C is a 90-degree hybrid circuit that performs a differential operation. The 90-degree hybrid circuit 11C includes windings L1, L2, L3, and L4 and cores 81 and 82.

The winding L1 is wound around the core 81. The winding L2 is wound around the core 81 in a direction opposite to the direction in which the winding L1 is wound (opposite winding direction). The winding L3 is wound around the core 82 in a direction opposite to the direction in which the winding L1 is wound (opposite winding direction). The winding L4 is wound around the core 82 in the same direction as the direction in which the winding L1 is wound (same winding direction).

One end of the winding L1 is electrically connected to the first amplifier 71 in the amplifier 2A. The other end of the winding L1 is electrically connected to the first amplifier 73 in the carrier amplifier 12A. One end of the winding L2 is electrically connected to the reference potential. The other end of the winding L2 is electrically connected to the first amplifier 77 in the peak amplifier 16A.

One end of the winding L3 is electrically connected to the reference potential. The other end of the winding L3 is electrically connected to the second amplifier 78 in the peak amplifier 16A. One end of the winding L4 is electrically connected to the second amplifier 72 in the amplifier 2A. The other end of the winding L4 is electrically connected to the second amplifier 74 in the carrier amplifier 12A.

Operation of the power amplifier circuit 1B is similar to operation of the power amplifier circuit 1A, and description of the operation of the power amplifier circuit 1B will be omitted.

### Second Embodiment

Component elements of a power amplifier circuit according to the second embodiment that are the same as component elements in the first embodiment are denoted by the same reference signs, and description of the same component elements will be omitted.

### (Entire Configuration)

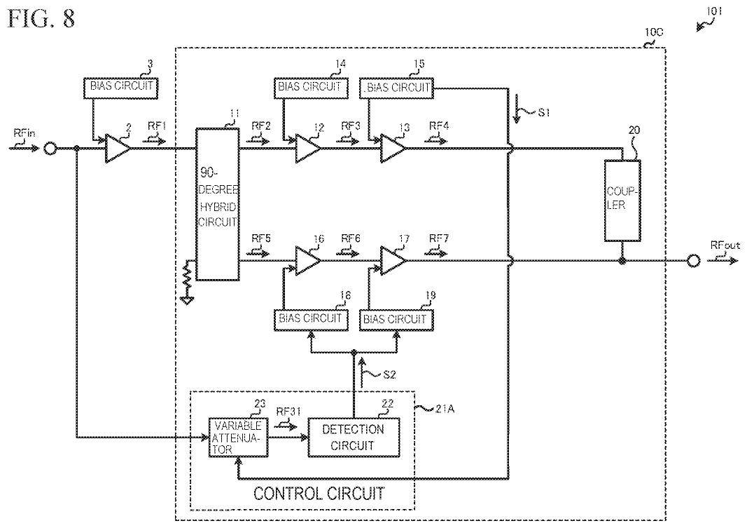

FIG. 8 is a diagram illustrating a configuration of the power amplifier circuit according to the second embodiment.

Unlike the power amplifier circuit 1 according to the first embodiment (see FIG. 1), a power amplifier circuit 101 includes a Doherty amplifier circuit 10C, instead of the Doherty amplifier circuit 10. Unlike the Doherty amplifier circuit 10, the Doherty amplifier circuit 10C includes a control circuit 21A, instead of the control circuit 21. Unlike the control circuit 21 (see FIG. 1), the control circuit 21A further includes a variable attenuator 23.

The number of stages of the Doherty amplifier circuit 10C is two. However, the present disclosure is not limited to this example. The number of stages of the Doherty amplifier circuit 10C may be one or three or more.

The high frequency signal RFin and the signal S1 indicating the drive level of the carrier amplifier 13 are input to the variable attenuator 23. Instead of the high frequency signal RFin, a high frequency signal RF1 may be input to the variable attenuator 23.

The variable attenuator 23 attenuates the high frequency signal RFin on the basis of the signal S1, and outputs an attenuated high frequency signal RF31. The detection circuit 22 outputs the signal S2 to the bias circuits 18 and 19 on the basis of the high frequency signal RF31.

In the first embodiment, a bias point of the detection circuit 22 is changed according to the signal S1.

In contrast, in the second embodiment, the bias point of the detection circuit 22 is fixed. The amount of attenuation at the variable attenuator 23, which is provided in a stage preceding the detection circuit 22, is changed according to the signal S1. Thus, the control circuit 21A is capable of outputting the signal S2 corresponding to the drive level of the carrier amplifier 13.

### Specific Example of Detection Circuit and Variable Attenuator

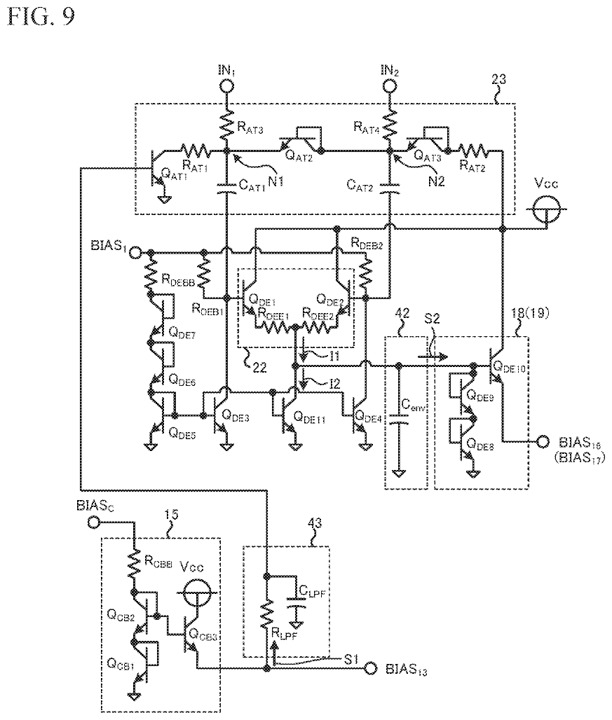

FIG. 9 is a diagram illustrating a specific example of the detection circuit and the variable attenuator in the power amplifier circuit according to the second embodiment.

The base of the transistor Q_{DE11} is electrically connected to the collector and base of the transistor Q_{DE5}. Thus, in the second embodiment, the collector current I2 is fixed.

The variable attenuator 23 includes resistors R_{AT1}, R_{AT2}, R_{AT3}, and R_{AT4}, transistors Q_{AT1}, Q_{AT2}, and Q_{AT3}, and capacitors C_{AT1} and C_{AT2}.

One end of the resistor R_{AT2} is electrically connected to the power supply potential Vcc. The other end of the resistor R_{AT2} is electrically connected to the collector and base of the transistor Q_{AT3}. That is, the transistor Q_{AT3} is diode-connected. The emitter of the transistor Q_{AT3} is electrically connected to a node N2.

The collector and base of the transistor Q_{AT2} is electrically connected to the node N2. That is, the transistor Q_{AT2} is diode-connected. The emitter of the transistor Q_{AT2} is electrically connected to a node N1.

One end of the resistor R_{AT1} is electrically connected to the node N1. The other end of the resistor R_{AT1} is electrically connected to the collector of the transistor Q_{AT1}. The emitter of the transistor Q_{AT1} is electrically connected to the reference potential. The signal S1 that has been low-pass filtered by the low pass filter 43 is input to the base of the transistor Q_{AT1}.

The high frequency signal IN₁ is input to one end of the resistor R_{AT3}. The other end of the resistor R_{AT3} is electrically connected to the node N1. One end of the capacitor C_{AT1} is electrically connected to the node N1. The other end of the capacitor C_{AT1} is electrically connected to the base of the transistor Q_{DE1}.

The high frequency signal IN₂ is input to one end of the resistor R_{AT4}. The other end of the resistor R_{AT4} is electrically connected to the node N2. One end of the capacitor C_{AT2} is electrically connected to the node N2. The other end of the capacitor C_{AT2} is electrically connected to the base of the transistor Q_{DE2}.

The variable attenuator 23 is an attenuator that uses the principle that the equivalent resistance of the transistor Q_{AT1} decreases as the current flowing in the transistor Q_{AT1} increases.

In the case where the drive level of the carrier amplifier 13 is relatively low, a relatively high voltage is input to the base of the transistor Q_{AT1}, which is a control terminal for the variable attenuator 23. At this time, a large amount of collector current of the transistor Q_{AT1} flows, and a large amount of current also flows in the transistors Q_{AT2} and Q_{AT3}. Thus, the equivalent resistance of the transistors Q_{AT1}, Q_{AT2}, and Q_{AT3} decreases, and the nodes N1 and N2 to which the high frequency signals IN₁ and IN₂ are transmitted enter a state close to short circuit. Therefore, the variable attenuator 23 does not allow the frequency signals IN₁ and IN₂ to pass therethrough.

In contrast, in the case where the drive level of the carrier amplifier 13 is relatively high, current does not flow to the transistors Q_{AT1}, Q_{AT2}, and Q_{AT3}. Thus, the variable attenuator 23 allows the frequency signals IN₁ and IN₂ to pass therethrough.

By providing the variable attenuator 23 in the stage preceding the detection circuit 22, the detection circuit 22 is capable of outputting the signal S2 corresponding to the drive level of the carrier amplifier 13.

The variable attenuator 23 substantially needs to control bandpass characteristics (attenuation characteristics) and delay of the input/output characteristics of the frequency signals IN₁ and IN₂ only needs to be small. Thus, various types of devices such as a variable gain amplifier may be used as the variable attenuator 23.

By providing the variable attenuator 23 as in the second embodiment, the sensitivity of output of the detection circuit 22 with respect to the drive level of the carrier amplifier 13 can be designed freely, and it is obvious that designing can be done easily.

In the second embodiment, in addition to a stabilization effect as in the first embodiment, an effect of further stabilization can be achieved. Reasons for these effects will be described below.

In the configuration of the first embodiment (see FIG. 5), although a path from a position (the emitter of the transistor Q_{CB3}) at which the carrier amplifier 13 is biased to a position (the emitter of the transistor Q_{DE10}) at which the peak amplifier 16 (17) is biased includes the low pass filter 43 and other elements, direct connection is made in terms of DC. That is, the path mentioned above is in a direct-connection state in the vicinity of DC (DC and low frequency region). In particular, since the transistor Q_{DE11} serves as a line connection for grounded-emitter amplification and the transistor Q_{DE10} serves as a line connection for grounded-collector amplification, an amplification effect may occur at the path. If the amplification effect occurs at the path, oscillation may occur in the worst case.

In contrast, in the configuration of the second embodiment (see FIG. 9), a path from a position (the emitter of the transistor Q_{CB3}) at which the carrier amplifier 13 is biased to a position (the emitter of the transistor Q_{DE10}) at which the peak amplifier 16 (17) is biased is interrupted in terms of DC by the capacitors C_{AT1} and C_{AT2}. Thus, in the vicinity of DC (DC and low frequency region), the isolation between the carrier amplifier 13 and the peak amplifier 16 (17) can be achieved, and an effect of suppressing occurrence of oscillation at the path can be achieved.

### Modifications

As in the first modification (see FIG. 6) and the second modification (see FIG. 7) of the first embodiment, each amplifier may be a differential amplifier in the second embodiment.

### Third Embodiment

Component elements of a power amplifier circuit according to a third embodiment that are the same as component elements in other embodiments are denoted by the same reference signs, and description of the same component elements will be omitted.

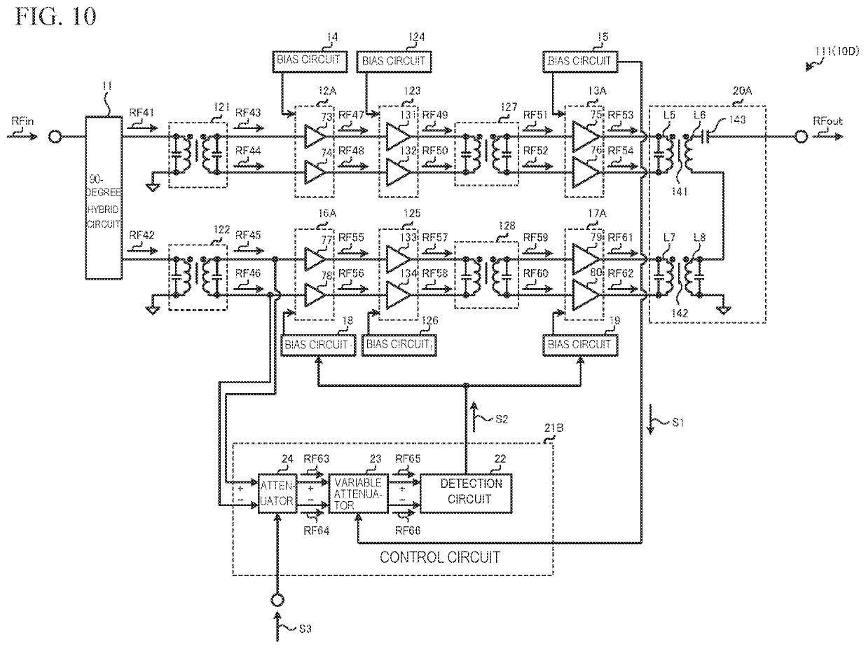

FIG. 10 is a diagram illustrating a configuration of the power amplifier circuit according to the third embodiment.

A power amplifier circuit 111 (Doherty amplifier circuit 10D) includes the 90-degree hybrid circuit 11, baluns 121, 122, 127, and 128, the initial-stage carrier amplifier 12A, an intermediate-stage carrier amplifier 123, the final-stage carrier amplifier 13A, bias circuits 14, 15, and 124, the initial-stage peak amplifier 16A, an intermediate-stage peak amplifier 125, the final-stage peak amplifier 17A, bias circuits 18, 19, and 126, the coupler 20A, and a control circuit 21B.

The number of stages of the Doherty amplifier circuit 10D is three. However, the present disclosure is not limited to this example. The number of stages of the Doherty amplifier circuit 10D may be two or less or four or more.

Each of the carrier amplifiers 12A, 13A, and 123 and the peak amplifiers 16A, 17A, and 125 is a differential amplifier.

The 90-degree hybrid circuit 11 divides the high frequency signal RFin into high frequency signals RF41 and RF42 whose phases are different by approximately 90 degrees. The 90-degree hybrid circuit 11 outputs the high frequency signal RF41 to one end of a first winding of the balun 121, and outputs the high frequency signal RF42 to one end of a first winding of the balun 122. The other end of the first winding of the balun 121 and the other end of the first winding of the balun 122 are electrically connected to the reference potential.

The balun 121 outputs, through corresponding ends of a second winding thereof, high frequency signals RF43 and RF44 configuring differential signals, on the basis of the input high frequency signal RF41.

The balun 122 outputs, through corresponding ends of a second winding thereof, high frequency signals RF45 and RF46 configuring differential signals, on the basis of the input high frequency signal RF42.

The first amplifier 73 in the carrier amplifier 12A outputs a high frequency signal RF47 obtained by amplifying the high frequency signal RF43 to the carrier amplifier 123. The second amplifier 74 in the carrier amplifier 12A outputs a high frequency signal RF48 obtained by amplifying the high frequency signal RF44 to the carrier amplifier 123.

The bias circuit 124 applies a bias to the carrier amplifier 123. A first amplifier 131 in the carrier amplifier 123 outputs a high frequency signal RF49 obtained by amplifying the high frequency signal RF47 to one end of a first winding of the balun 127. A second amplifier 132 in the carrier amplifier 123 outputs a high frequency signal RF50 obtained by amplifying the high frequency signal RF48 to the other end of the first winding of the balun 127.

The balun 127 outputs, through corresponding ends of a second winding thereof, high frequency signals RF51 and RF52 configuring differential signals, on the basis of the input high frequency signals RF49 and RF50.

The first amplifier 75 in the carrier amplifier 13A outputs a high frequency signal RF53 obtained by amplifying the high frequency signal RF51 to one end of a first winding L5 of the coupler 20A. The second amplifier 76 in the carrier amplifier 13A outputs a high frequency signal RF54 obtained by amplifying the high frequency signal RF52 to the other end of the first winding L5 of the coupler 20A.

The first amplifier 77 in the peak amplifier 16A outputs a high frequency signal RF55 obtained by amplifying the high frequency signal RF45 to the peak amplifier 125. The second amplifier 78 in the peak amplifier 16A outputs a high frequency signal RF56 obtained by amplifying the high frequency signal RF46 to the peak amplifier 125.

The bias circuit 126 applies a bias to the peak amplifier 125. A first amplifier 133 in the peak amplifier 125 outputs a high frequency signal RF57 obtained by amplifying the high frequency signal RF55 to one end of a first winding of the balun 128. A second amplifier 134 in the peak amplifier 125 outputs a high frequency signal RF58 obtained by amplifying the high frequency signal RF56 to the other end of the first winding of the balun 128.

The balun 128 outputs, through corresponding ends of a second winding thereof, high frequency signals RF59 and RF60 configuring a pair of differential signals, on the basis of the input high frequency signals RF57 and RF58.

The first amplifier 79 in the peak amplifier 17A outputs a high frequency signal RF61 obtained by amplifying the high frequency signal RF59 to one end of a third winding L7 of the coupler 20A. The second amplifier 80 in the peak amplifier 17A outputs a high frequency signal RF62 obtained by amplifying the high frequency signal RF60 to the other end of the third winding L7 of the coupler 20A.

The first winding L5 in the coupler 20A is wound around a core 141. A second winding L6 in the coupler 20A is wound around the core 141 in the same direction as the direction in which the first winding L5 is wound (same winding direction). The third winding L7 in the coupler 20A is wound around a core 142 in the same direction as the direction in which the first winding L5 is wound (same winding direction). A fourth winding L8 in the coupler 20A is wound around the core 142 in the same direction as the direction in which the third winding L7 is wound (same winding direction). One end of the second winding L6 and one end of the fourth winding L8 are electrically connected. The other end of the fourth winding L8 is electrically connected to the reference potential. The high frequency signal RFout is output from the other end of the second winding L6 through the capacitor 143.

Unlike the control circuit 21A (see FIG. 8), the control circuit 21B further includes an attenuator 24.

The high frequency signals RF45 and RF46 forming differential signals are input to the attenuator 24. Instead of the high frequency signals RF45 and RF46, the high frequency signals RF43 and RF44 may be input to the attenuator 24. The attenuator 24 outputs high frequency signals RF63 and RF64 obtained by attenuating the high frequency signals RF45 and RF46, respectively, to the variable attenuator 23. It is desirable that the amount of attenuation at the attenuator 24 be adjustable in accordance with a control signal S3 from the outside.

The high frequency signals RF63 and RF64 and the signal S1 indicating the drive level of the carrier amplifier 13A are input to the variable attenuator 23.

The control circuit 21B controls not only the bias circuit 19 that applies a bias to the final-stage peak amplifier 17A but also the bias circuit 18 that applies a bias to the initial-stage peak amplifier 16A.

Changes in features between the power amplifier circuit 101 according to the second embodiment (see FIG. 8) and the power amplifier circuit 111 according to the third embodiment (see FIG. 10) and effects achieved by the changes will be described.

Firstly, in the case where the peak amplifiers 16 and 17 are single-end amplifiers as in the power amplifier circuit 101 according to the second embodiment, a high frequency signal causes the peak amplifiers 16 and 17 to oscillate and part of the high frequency signal causes the emitter of the transistor Q_{DE10} inside the bias circuits 18 and 19 (see FIG. 9) to vibrate. In the case where the high frequency signal is large, this vibration causes the transistor Q_{DE10} to perform a detection operation, which may be an unintended operation.

In contrast, in the power amplifier circuit 111 according to the third embodiment, by using differential amplifiers as the all stages of carrier amplifiers and peak amplifiers, the possibility of high frequency signals flowing into the bias circuit side from bias voltage input terminals of the peak amplifiers 16A, 125, and 17A can be reduced.

Secondly, as described above, in the power amplifier circuit 111 according to the third embodiment, by using differential amplifiers as the peak amplifiers 16A, 125, and 17A, an unintended detection operation by the transistor Q_{DE10} can be significantly reduced. However, even if differential amplifiers are used as the peak amplifiers 16A, 125, and 17A, the differential amplifiers are less likely to operate at exactly opposite phases. Thus, a high frequency signal may flow into the bias circuit side from the bias voltage input terminal of each of the peak amplifiers 16A, 125, and 17A.

In the power amplifier circuit 111 according to the third embodiment, the control circuit 21B controls the bias circuit 18 that applies a bias to the initial-stage peak amplifier 16A as well as the bias circuit 19 that applies a bias to the final-stage peak amplifier 17A. Thus, since a high frequency signal that flows into the bias circuit 18 side from the peak amplifier 16A can be suppressed, the possibility that the transistor Q_{DE10} performs a detection operation can further be reduced.

Thirdly, for example, the case where environmental temperature drops and the total gain of all stages of carrier amplifiers increases will be considered. In such a case, typically, since the gain increases, the final-stage carrier amplifier 13A may saturate even when input power is low.

In the power amplifier circuit 1 according to the first embodiment (see FIG. 1) and the power amplifier circuit 101 according to the second embodiment (see FIG. 8), the drive level of the carrier amplifier 13 (13A) is detected, and the bias of the peak amplifier 16 (17) is controlled. Thus, since a mechanism for causing the peak amplifier 16 (17) to rise with a low input power works even at a low temperature, the possibility that the carrier amplifier 13 (13A) independently saturates is low. However, with not only low temperature but also variations in load and other factors, the control range of the single variable attenuator 23 may be insufficient.

Thus, the power amplifier circuit 111 according to the third embodiment includes the attenuator 24 that is capable of adjusting the amount of attenuation in accordance with the control signal S3 from the outside. It is desirable that adjustment of the amount of attenuation at the attenuator 24 be performed in the case where it is clear from a change in environment or conditions that input power for causing the peak amplifier 16A (17A) to rise has been changed. In the power amplifier circuit 111 according to the third embodiment, it is desirable that the amount of attenuation at the attenuator 24 be externally adjusted on the basis of information about ambient temperature, external load conditions, or characteristics of an input signal (center frequency, average power, PAPR (Peak to Average Power Ratio), etc.), or history information about the ambient temperature, the external load conditions, or the characteristics of the input signal.

Thus, even if environment or conditions change, the power amplifier circuit 111 according to the third embodiment can reduce the possibility that the carrier amplifier 13A saturates.

Although the control circuit 21B controls the bias circuits 18 and 19 in the third embodiment, the present disclosure is not limited to this example. The control circuit 21B may also control the bias circuit 126. The control circuit 21B may control at least the bias circuit 18 that applies a bias to the initial-stage peak amplifier 16A and the bias circuit 19 that applies a bias to the final-stage peak amplifier 17A.

### Fourth Embodiment

Component elements of a power amplifier circuit according to a fourth embodiment that are the same as component elements in other embodiments are denoted by the same reference signs, and description of the same component elements will be omitted.

Although the signal S1 indicating the drive level of the carrier amplifier 13 is processed at the detection circuit 22 or in a stage preceding the detection circuit 22 and the processed signal S1 is reflected in the signal S2 in the first embodiment and the second embodiment, the present disclosure is not limited to this example. The signal S1 indicating the drive level of the carrier amplifier 13 may be added to a signal output from the detection circuit 22.

### (Entire Configuration)

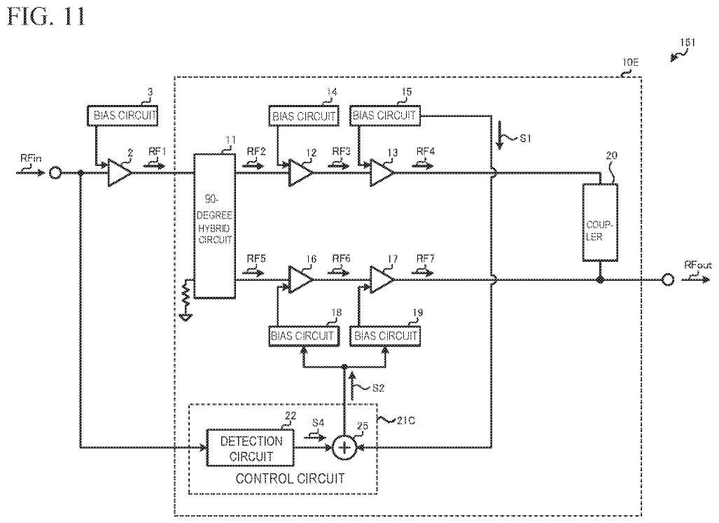

FIG. 11 is a diagram illustrating a configuration of the power amplifier circuit according to the fourth embodiment.

Unlike the power amplifier circuit 1 according to the first embodiment (see FIG. 1), a power amplifier circuit 151 includes a Doherty amplifier circuit 10E, instead of the Doherty amplifier circuit 10. Unlike the Doherty amplifier circuit 10, the Doherty amplifier circuit 10E includes a control circuit 21C, instead of the control circuit 21. Unlike the control circuit 21 (see FIG. 1), the control circuit 21C further includes an adder circuit 25.

The adder circuit 25 corresponds to an example of a “bias control circuit” according to the present disclosure.

The number of stages of the Doherty amplifier circuit 10E is two. However, the present disclosure is not limited to this example. The number of stages of the Doherty amplifier circuit 10E may be one or three or more.

The high frequency signal RFin is input to the detection circuit 22. Instead of the high frequency signal RFin, the high frequency signal RF1 may be input to the detection circuit 22.

The detection circuit 22 outputs a signal S4 to the adder circuit 25 on the basis of the high frequency signal RFin.

The signal S1 indicating the drive level of the carrier amplifier 13 is input to the adder circuit 25. The signal S1 may be output from the bias circuit 15 or may be output from the carrier amplifier 13.

The adder circuit 25 outputs the signal S2, which is obtained by adding the signal S1 and the signal S4, to the bias circuits 18 and 19.

### Specific Example of Detection Circuit and Adder Circuit

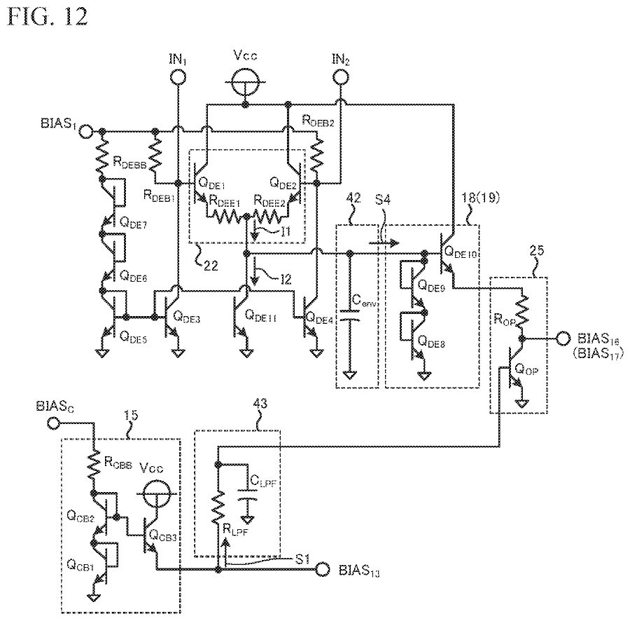

FIG. 12 is a diagram illustrating a specific example of the detection circuit and the adder circuit in the power amplifier circuit according to the fourth embodiment.

The adder circuit 25 includes a resistor R_{OP} and a transistor Q_{OP}.

One end of the resistor R_{OP} is electrically connected to the emitter of the transistor Q_{DE10}. The other end of the resistor R_{OP} is electrically connected to the collector of the transistor Q_{OP}. The base of the transistor Q_{OP} is electrically connected to the other end of the resistor R_{LPF} and one end of the capacitor C_{LPF}. The emitter of the transistor Q_{OP} is electrically connected to the reference potential. The bias voltage BIAS₁₆ (BIAS₁₇) is output from a connection point of the other end of the resistor R_{OP} and the collector of the transistor Q_{OP}.

As described above in other embodiments, the signal S1 is a signal (inversion signal) that changes in a complementary manner according to the drive level of the carrier amplifier 13. Thus, the adder circuit 25 subtracts the signal S1 from the signal S2 (adds a minus S1 signal) and thus outputs the bias voltage BIAS₁₆ (BIAS₇).

The transistor Q_{OP} converts the signal S1 input to the base thereof into a collector current. The bias voltage BIAS₁₆ (BIAS₁₇) is a voltage obtained by subtracting a voltage drop represented by the product of the collector current value of the transistor Q_{OP} and the resistance of the resistor R_{OP} from the output voltage of the bias circuit 18 (19).

### Modifications

As in the first modification (see FIG. 6) and the second modification (see FIG. 7) of the first embodiment, each amplifier may be a differential amplifier in the fourth embodiment.

### Fifth Embodiment

Component elements of a power amplifier circuit according to a fifth embodiment that are the same as component elements in other embodiments are denoted by the same reference signs, and description of the same component elements will be omitted.

### (Entire Configuration)

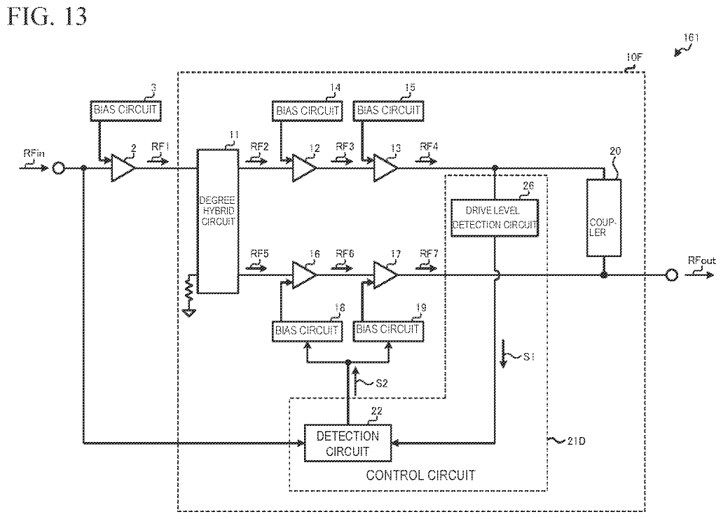

FIG. 13 is a diagram illustrating a configuration of the power amplifier circuit according to the fifth embodiment.

Unlike the power amplifier circuit 1 according to the first embodiment (see FIG. 1), a power amplifier circuit 161 includes a Doherty amplifier circuit 10F, instead of the Doherty amplifier circuit 10. Unlike the Doherty amplifier circuit 10, the Doherty amplifier circuit 10F includes a control circuit 21D, instead of the control circuit 21. Unlike the control circuit 21 (see FIG. 1), the control circuit 21D further includes a drive level detection circuit 26.

The number of stages of the Doherty amplifier circuit 10F is two. However, the present disclosure is not limited to this example. The number of stages of the Doherty amplifier circuit 10F may be one or three or more.

The drive level detection circuit 26 outputs the signal S1 indicating the drive level of the carrier amplifier 13 to the detection circuit 22 on the basis of the high frequency signal RF4 output from the carrier amplifier 13.

The high frequency signal RFin and the signal S1 are input to the detection circuit 22. Instead of the high frequency signal RFin, the high frequency signal RF1 may be input to the detection circuit 22.

The detection circuit 22 outputs the signal S2 for controlling the bias circuits 18 and 19 to the bias circuits 18 and 19 on the basis of the high frequency signal RFin and the signal S1. The bias circuit 18 applies a bias to the peak amplifier 16 on the basis of the signal S2. The bias circuit 19 applies a bias to the peak amplifier 17 on the basis of the signal S2.

### Specific Example of Detection Circuit and Drive Level Detection Circuit

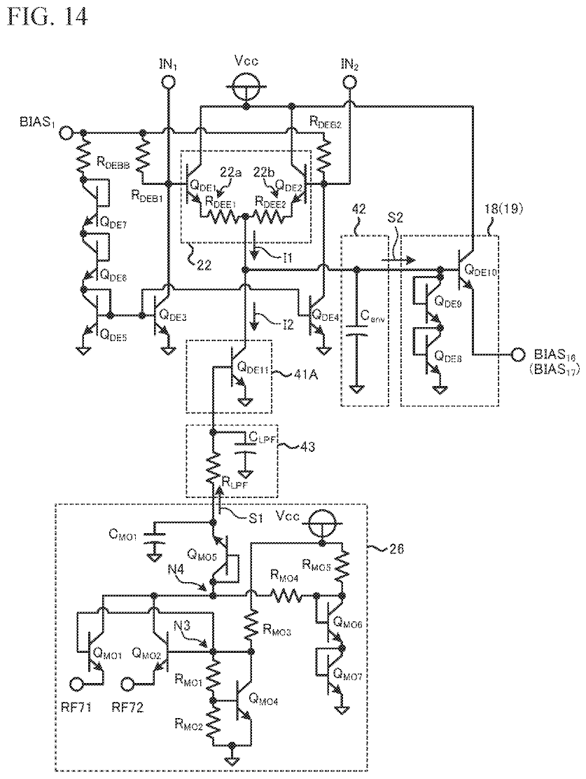

FIG. 14 is a diagram illustrating a specific example of the detection circuit and the drive level detection circuit in the power amplifier circuit according to the fifth embodiment.

The drive level detection circuit 26 includes resistors R_{MO1}, R_{MO2}, R_{MO3}, R_{MO4}, and R_{MO5}, transistors Q_{MO1}, Q_{MO2}, Q_{MO4}, Q_{MO5}, Q_{MO6}, and Q_{MO7}, and a capacitor C_{MO1}.

In this specific example, the carrier amplifier 13 (see FIG. 13) is a differential amplifier and outputs high frequency signals RF71 and RF72 configuring a pair of differential signals.

The high frequency signal RF71 is input to the emitter of the transistor Q_{MO1}. The emitter of the transistor Q_{MO1} is illustrated as being electrically connected to an output terminal (the collector or drain of an output transistor) of one amplifier in the carrier amplifier 13.

The high frequency signal RF72 is input to the emitter of the transistor Q_{MO2}. The emitter of the transistor Q_{MO2} is illustrated as being electrically connected to an output terminal (the collector or drain of an output transistor) of the other amplifier in the carrier amplifier 13.

The base of the transistor Q_{MO1} and the base of the transistor Q_{MO2} are electrically connected to a node N3.

The collector of the transistor Q_{MO1} and the collector of the transistor Q_{MO2} are electrically connected to a node N4.

The resistors R_{MO1}, R_{MO2}, and R_{MO3} and the transistor Q_{MO4} apply voltages to the node N3. That is, the resistors R_{MO1}, R_{MO2}, and R_{MO3} and the transistor Q_{MO4} apply biases to the base of the transistor Q_{MO1} and the base of the transistor Q_{MO2}.

One end of the resistor R_{MO3} is electrically connected to the power supply potential Vcc. The other end of the resistor R_{MO3} is electrically connected to the node N3, the collector of the transistor Q_{MO4}, and one end of the resistor R_{MO1}. The other end of the resistor R_{MO1} is electrically connected to the base of the transistor Q_{MO4} and one end of the resistor R_{MO2}. The emitter of the transistor Q_{MO4} and the other end of the resistor R_{MO2} are electrically connected to the reference potential. The resistors R_{MO1} and R_{MO2} and the transistor Q_{MO4} generate a constant voltage. This voltage serves as the voltage of the node N3.

The resistors R_{MO4} and R_{MO5} and the transistors Q_{MO6} and Q_{MO7} apply voltages to the node N4. That is, the resistors R_{MO4} and R_{MO5} and the transistors Q_{MO6} and Q_{MO7} apply biases to the collector of the transistor Q_{MO1} and the collector of the transistor Q_{MO2}.

One end of the resistor R_{MO5} is electrically connected to the power supply potential Vcc. The other end of the resistor R_{MO5} is electrically connected to the collector and base of the transistor Q_{MO6}. That is, the transistor Q_{MO6} is diode-connected. The emitter of the transistor Q_{MO6} is electrically connected to the collector and base of the transistor Q_{MO7}. That is, the transistor Q_{MO7} is diode-connected. The emitter of the transistor Q_{MO7} is electrically connected to the reference potential. One end of the resistor R_{MO4} is electrically connected to the other end of the resistor R_{MO5} and the collector and base of the transistor Q_{MO6}. The other end of the resistor R_{MO4} is electrically connected to the node N4. The transistors Q_{MO6} and Q_{MO7} generate a constant voltage. This voltage serves as the voltage of the node N4 through the resistor R_{MO4}.

The collector and base of the transistor Q_{MO5} is electrically connected to the node N4. That is, the transistor Q_{MO5} is diode-connected. The emitter of the transistor Q_{MO5} is electrically connected to one end of the capacitor C_{MO1}. The other end of the capacitor C_{MO5} is electrically connected to the reference potential.

The transistor Q_{MO5} outputs, through the emitter thereof, the signal S1. The capacitor C_{MO1} smooths the signal S1 by shunting a high frequency component of the signal S1.

The resistors R_{MO1}, R_{MO2}, and R_{MO3} and the transistor Q_{MO4} only need to output a roughly constant voltage and may be considered as a constant voltage source. The resistor R_{MO5} and the transistors Q_{MO6} and Q_{MO7} only need to output a roughly constant voltage and may be considered as a constant voltage source. The transistor Q_{MO5} only needs to generate a roughly constant voltage drop and may be considered as a constant voltage source.

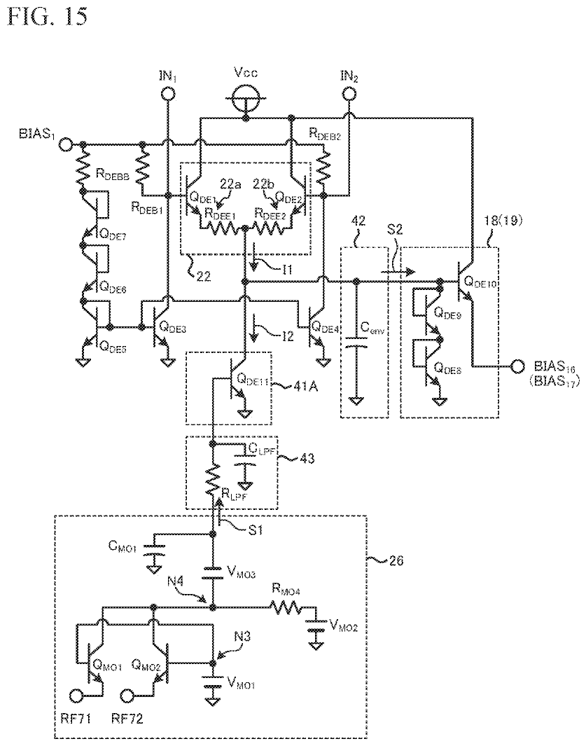

FIG. 15 is a diagram illustrating an equivalent circuit of a specific example of the detection circuit and the drive level detection circuit in the power amplifier circuit according to the fifth embodiment.

A constant voltage source V_{MO1} in FIG. 15 corresponds to the resistors R_{MO1}, R_{MO2}, and R_{MO3} and the transistor Q_{MO4} in FIG. 14. A constant voltage source V_{MO2} in FIG. 15 corresponds to the resistor R_{MO5} and the transistors Q_{MO6} and Q_{MO7} in FIG. 14. A constant voltage source V_{MO3} in FIG. 15 corresponds to the transistor Q_{MO5} in FIG. 14.

### (Operation of Drive Level Detection Circuit)

An operation of the drive level detection circuit 26 will be described with reference to the equivalent circuit of FIG. 15.

Typically, the output terminal voltage of the final-stage carrier amplifier vibrates at a voltage amplitude of a high frequency signal centered at a bias voltage. When the final-stage carrier amplifier saturates, a situation in which the voltage amplitude of a high frequency signal increases to be substantially equal to the bias voltage occurs. In such a situation, the moment at which the output terminal voltage approaches 0 V occurs during the amplitude period of the high frequency signal. At this moment, no amplification effect is obtained, which leads to a phenomenon such as saturation of an amplifier.

A circuit in this specific example uses this principle of saturation and thus detects the drive level of the carrier amplifier 13.

Specifically, in the periods of the high frequency signals RF71 and RF72, for only the periods during which the voltages of the high frequency signals RF71 and RF72 are lower than a voltage obtained by subtracting a voltage drop equivalent to a threshold voltage for the transistors Q_{MO1} and Q_{MO2} from the voltage of the constant voltage source V_{MO1}, the transistors Q_{MO1} and Q_{MO2} are in the ON state.

When the carrier amplifier 13 operates in a state in which saturation is least likely to occur, the transistors Q_{MO1} and Q_{MO2} do not have an ON period, and collector current does not flow. Therefore, no current flows to the resistor R_{MO4}, and no voltage drop occurs. Thus, the signal S1 is a voltage obtained by subtracting the voltage of the constant voltage source V_{MO3} from the voltage of the constant voltage source V_{MO2}.

In contrast, when the amplitude of the high frequency signals RF71 and RF72 increases, the transistors Q_{MO1} and Q_{MO2} have an ON period, and collector current flows. Therefore, current flows to the resistor R_{MO4}, and a voltage drop occurs.

When the amplitude of the high frequency signals RF71 and RF72 further increases, the length of the ON period of the transistors Q_{MO1} and Q_{MO2} increases. Thus, a larger amount of collector current flows. Therefore, a larger amount of current flows to the resistor R_{MO4}, and a larger voltage drop occurs.

Thus, as the drive level of the carrier amplifier 13 increases, the voltage of the signal S1 becomes a value reduced by the voltage drop at the resistor R_{MO4} from the voltage when the high frequency signals RF71 and RF72 are small. The signal S1 can be regarded as a signal (inversion signal) that changes in a complementary manner according to the drive level of the carrier amplifier 13. Thus, the bias of the detection circuit 22 and the circuit configurations of the variable attenuator 23 and the adder circuit 25 described above in the first to fourth embodiments can also be used in this embodiment.

### Modifications

As in the first modification (see FIG. 6) and the second modification (see FIG. 7) according to the first embodiment, each amplifier may be a differential amplifier in the fifth embodiment.

As in the second embodiment, the variable attenuator 23 may be provided in the stage preceding the detection circuit 22 in the fifth embodiment so that the drive level detection circuit 26 can output the signal S1 to the variable attenuator 23.

As in the third embodiment, the attenuator 24 may be provided in the stage preceding the variable attenuator 23 in the fifth embodiment.

As in the fourth embodiment, the adder circuit 25 may be provided in the stage following the detection circuit 22 in the fifth embodiment so that the adder circuit 25 can add the signal S4 output from the detection circuit 22 and the signal S1 output from the drive level detection circuit 26.

### Sixth Embodiment

Component elements of a power amplifier circuit according to a sixth embodiment that are the same as component elements in other embodiments are denoted by the same reference signs, and description of the same component elements will be omitted.

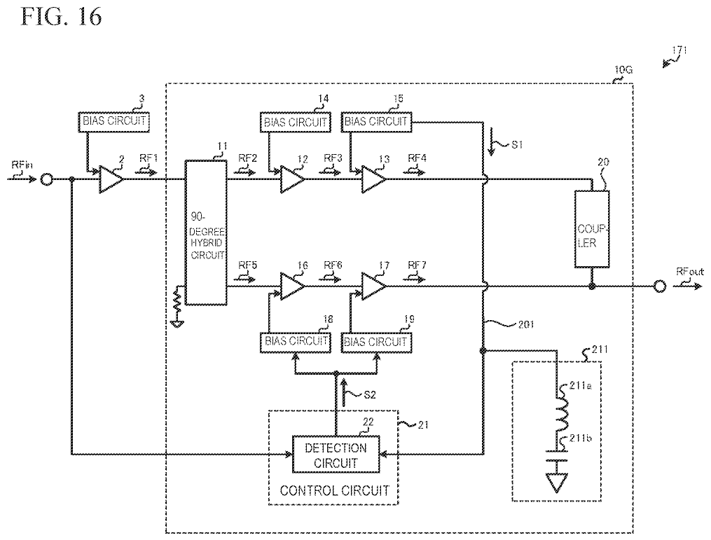

FIG. 16 is a diagram illustrating a configuration of the power amplifier circuit according to the sixth embodiment.

Unlike the power amplifier circuit 1 according to the first embodiment (see FIG. 1), a power amplifier circuit 171 includes a Doherty amplifier circuit 10G, instead of the Doherty amplifier circuit 10. Unlike the Doherty amplifier circuit 10, the Doherty amplifier circuit 10G further includes a series resonant circuit 211. The series resonant circuit 211 includes an inductor 211a and a capacitor 211b.

One end of the inductor 211a is electrically connected to a wire 201 between the bias circuit 15 and the control circuit 21. The other end of the inductor 211a is electrically connected to one end of the capacitor 211b. The other end of the capacitor 211b is electrically connected to the reference potential.

The series resonant circuit 211 shunts and reduces a resonant frequency component of the series resonant circuit 211 in the signal S1 to the reference potential.

Thus, the Doherty amplifier circuit 10G can reduce oscillation caused by a feedback loop.

In this embodiment, the series resonant circuit 211 includes the inductor 211a and the capacitor 211b. However, the present disclosure is not limited to this arrangement. The series resonant circuit 211 may have a circuit configuration including a resonator including a piezoelectric element.

Furthermore, in the case where the series resonant circuit 211 has a low resonant frequency, the low resonant frequency may affect communication quality. Thus, it is desirable that the resonant frequency be higher than the band width of a modulation signal.

### Seventh Embodiment

Component elements of a power amplifier circuit according to a seventh embodiment that are the same as component elements in other embodiments are denoted by the same reference signs, and description of the same component elements will be omitted.

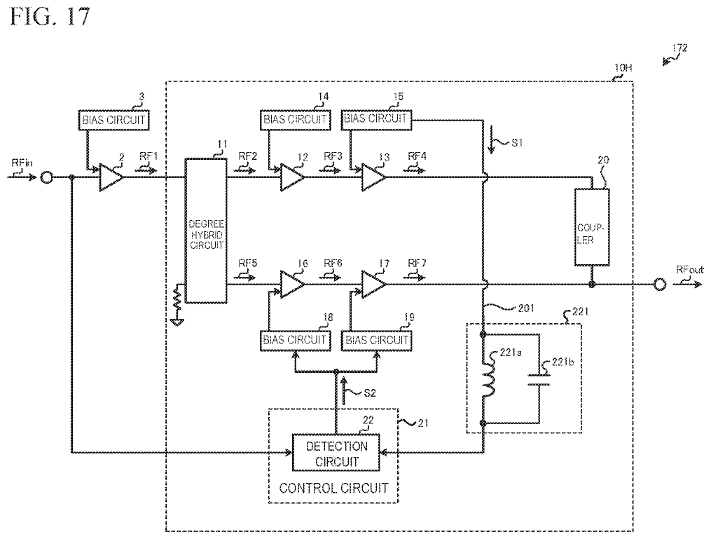

FIG. 17 is a diagram illustrating a configuration of the power amplifier circuit according to the seventh embodiment.

Unlike the power amplifier circuit 1 according to the first embodiment (see FIG. 1), a power amplifier circuit 172 includes a Doherty amplifier circuit 10H, instead of the Doherty amplifier circuit 10. Unlike the Doherty amplifier circuit 10, the Doherty amplifier circuit 10H further includes a parallel resonant circuit 221. The parallel resonant circuit 221 includes an inductor 221a and a capacitor 221b.

The inductor 221a is inserted in series into the wire 201 between the bias circuit 15 and the control circuit 21. The capacitor 221b is electrically connected in parallel to the inductor 221a.

The parallel resonant circuit 221 reduces a resonant frequency component of the parallel resonant circuit 221 in the signal S1.

Thus, the Doherty amplifier circuit 10H can reduce oscillation caused by a feedback loop.

In this embodiment, the parallel resonant circuit 221 includes the inductor 221a and the capacitor 221b. However, the present disclosure is not limited to this arrangement. The parallel resonant circuit 221 may have a circuit configuration including a resonator including a piezoelectric element.

Furthermore, in the case where the parallel resonant circuit 221 has a low resonant frequency, the low resonant frequency may affect communication quality. Thus, it is desirable that the resonant frequency be higher than the band width of a modulation signal.

### Eighth Embodiment

Component elements of a power amplifier circuit according to an eighth embodiment that are the same as component elements in other embodiments are denoted by the same reference signs, and description of the same component elements will be omitted.

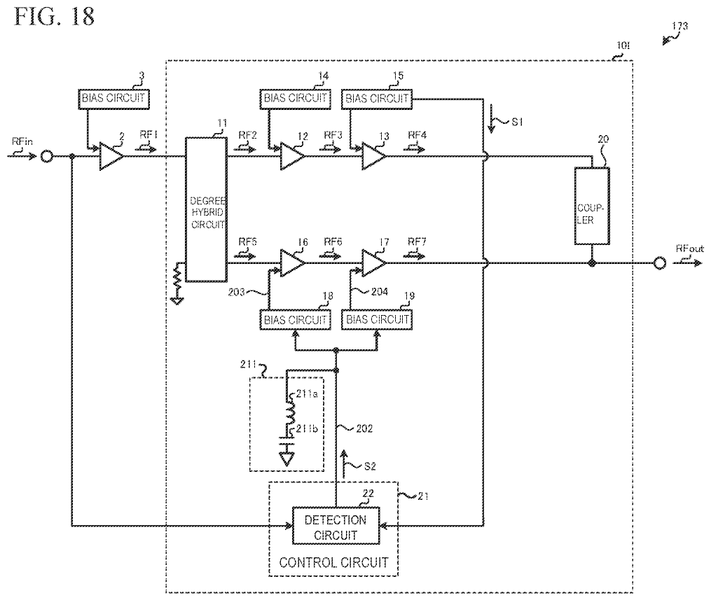

FIG. 18 is a diagram illustrating a configuration of the power amplifier circuit according to the eighth embodiment.

Unlike the power amplifier circuit 1 according to the first embodiment (see FIG. 1), a power amplifier circuit 173 includes a Doherty amplifier circuit 10I, instead of the Doherty amplifier circuit 10. Unlike the Doherty amplifier circuit 10, the Doherty amplifier circuit 10I further includes the series resonant circuit 211.

One end of the inductor 211a is electrically connected to a wire 202 between the control circuit 21 and the bias circuits 18 and 19. The other end of the inductor 211a is electrically connected to one end of the capacitor 211b. The other end of the capacitor 211b is electrically connected to the reference potential.

The series resonant circuit 211 shunts and reduces a resonant frequency component of the series resonant circuit 211 in the signal S2 to the reference potential.

Thus, the Doherty amplifier circuit 10I can reduce oscillation caused by a feedback loop.

In this embodiment, the series resonant circuit 211 is electrically connected to the wire 202. However, the present disclosure is not limited to this arrangement. The series resonant circuit 211 may be electrically connected to a wire 203 between the bias circuit 18 and the peak amplifier 16. Alternatively, the series resonant circuit 211 may be electrically connected to the wire 204 between the bias circuit 19 and the peak amplifier 17.

### Ninth Embodiment

Component elements of a power amplifier circuit according to a ninth embodiment that are the same as component elements in other embodiments are denoted by the same reference signs, and description of the same component elements will be omitted.

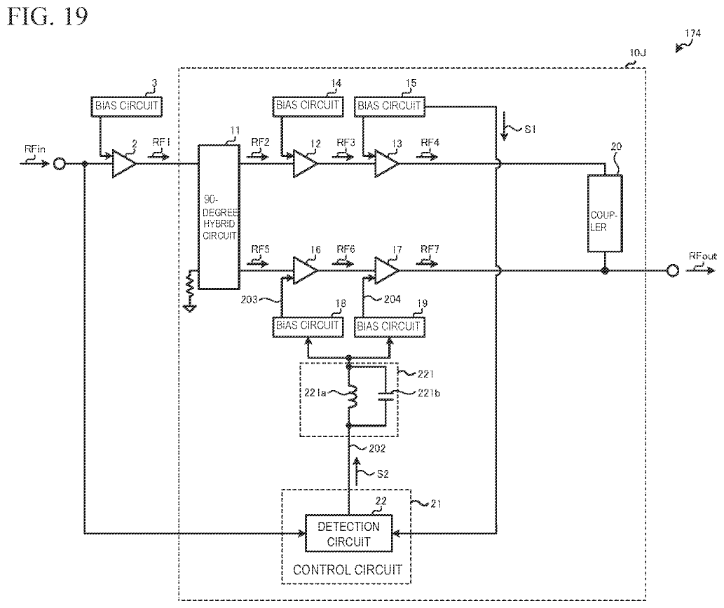

FIG. 19 is a diagram illustrating a configuration of the power amplifier circuit according to the ninth embodiment.

Unlike the power amplifier circuit 1 according to the first embodiment (see FIG. 1), a power amplifier circuit 174 includes a Doherty amplifier circuit 10J, instead of the Doherty amplifier circuit 10. Unlike the Doherty amplifier circuit 10, the Doherty amplifier circuit 10J further includes the parallel resonant circuit 221.

The inductor 221a is inserted in series into the wire 202 between the control circuit 21 and the bias circuits 18 and 19. The capacitor 221b is electrically connected in parallel to the inductor 221a.

The parallel resonant circuit 221 reduces a resonant frequency component of the parallel resonant circuit 221 in the signal S2.

Thus, the Doherty amplifier circuit 10J can reduce oscillation caused by a feedback loop.

In this embodiment, the parallel resonant circuit 221 is inserted into the wire 202. However, the present disclosure is not limited to this arrangement. The parallel resonant circuit 221 may be inserted into the wire 203 between the bias circuit 18 and the peak amplifier 16. Alternatively, the parallel resonant circuit 221 may be inserted into the wire 204 between the bias circuit 19 and the peak amplifier 17.

The embodiments described above are provided for easier understanding of the present disclosure and are not intended to be construed as limiting the present disclosure. The present disclosure may be altered/improved without necessarily departing from the spirit of the present disclosure and encompass equivalents thereof.

### REFERENCE SIGNS LIST

1, 1A, 1B, 101, 111, 151, 161, 171, 172, 173, 174 power amplifier circuit
2, 2A amplifier
3, 14, 15, 18, 19, 124, 126 bias circuit
10, 10A, 10B, 10C, 10D, 10E, 10F, 10G, 10H, 10I, 10J Doherty amplifier circuit
11, 11A, 11B, 11C 90-degree hybrid circuit
12, 12A, 13, 13A, 123 carrier amplifier
16, 16A, 17, 17A, 125 peak amplifier
20, 20A coupler
21, 21A, 21B, 21C, 21D control circuit
22 detection circuit
23 variable attenuator
24 attenuator
25 adder circuit
26 drive level detection circuit
41, 41A constant current circuit
42, 43 low pass filter
61, 121, 122, 127, 128 balun
211 series resonant circuit
211a, 221a inductor
211b, 221b capacitor
221 parallel resonant circuit

1. A Doherty amplifier circuit comprising:
a carrier amplifier configured to amplify a first input high frequency signal;
a peak amplifier configured to amplify a second input high frequency signal;
a first bias circuit configured to apply a first bias to the carrier amplifier;
a second bias circuit configured to apply a second bias to the peak amplifier; and
a control circuit configured to control the second bias circuit on the basis of an input high frequency signal and a signal indicating a drive level of the carrier amplifier.

2. The Doherty amplifier circuit according to claim 1, wherein the control circuit is configured to:
control the second bias circuit such that the second bias circuit increases a bias current applied to the peak amplifier as the drive level increases, and
control the second bias circuit such that the second bias circuit increases the bias current applied to the peak amplifier as power of an input high frequency signal increases.

3. The Doherty amplifier circuit according to claim 1, wherein high frequency signals input to the control circuit are differential signals.

4. The Doherty amplifier circuit according to claim 3, wherein the control circuit comprises:
a detection circuit that comprises a first emitter-follower or source-follower circuit, and a second emitter-follower or source-follower circuit,
a constant current circuit that is electrically connected to an output terminal of the detection circuit and that is configured to output a current corresponding to the signal indicating the drive level of the carrier amplifier, and
a capacitor having a first end electrically connected to the output terminal of the detection circuit,
wherein one of the differential signals is input to a base or gate of the first emitter-follower or source-follower circuit, and the other one of the differential signals is input to a base or gate of the second emitter-follower or source-follower circuit,
wherein a node at an output terminal of the first emitter-follower or source-follower circuit and at an output terminal of the second emitter-follower or source-follower circuit is an output terminal of the detection circuit, and
wherein the control circuit is configured to control the second bias circuit such that the second bias circuit outputs a bias current corresponding to a voltage of the capacitor.

5. The Doherty amplifier circuit according to claim 3, wherein the control circuit comprises:
a variable attenuator configured to attenuate the differential signals by an attenuation amount corresponding to the signal indicating the drive level of the carrier amplifier,
a detection circuit that comprises a first emitter-follower or source-follower circuit, and a second emitter-follower or source-follower circuit,
a constant current circuit that is electrically connected to an output terminal of the detection circuit and that is configured to output a constant current, and
a capacitor having a first end electrically connected to the output terminal of the detection circuit,
wherein one of the differential signals attenuated by the variable attenuator is input to a base of the first emitter-follower or source-follower circuit, and the other one of the differential signals attenuated by the variable attenuator is input to a base of the second emitter-follower or source-follower circuit,
wherein a node at an output terminal of the first emitter-follower or source-follower circuit and at an output terminal of the second emitter-follower or source-follower circuit is an output terminal of the detection circuit, and
wherein the control circuit is configured to control the second bias circuit such that the second bias circuit outputs a bias current corresponding to a voltage of the capacitor.

6. The Doherty amplifier circuit according to claim 5, wherein the control circuit further comprises an attenuator that is in a stage preceding the variable attenuator, the attenuator being configured to attenuate the differential signals by an attenuation amount corresponding to an input control signal and to output the attenuated differential signals to the variable attenuator.

7. The Doherty amplifier circuit according to claim 3, wherein the control circuit comprises:
a detection circuit that comprises a first emitter-follower or source-follower circuit, and a second emitter-follower or source-follower circuit,
a constant current circuit that is electrically connected to an output terminal of the detection circuit and that is configured to output a constant current,
a capacitor having a first end electrically connected to the output terminal of the detection circuit, and
a bias control circuit configured to control the second bias such that the second bias circuit outputs a bias current corresponding to a voltage of the capacitor and the signal indicating the drive level of the carrier amplifier,
wherein one of the differential signals is input to a base or gate of the first emitter-follower or source-follower circuit, and the other one of the differential signals is input to a base or gate of the second emitter-follower or source-follower circuit, and
wherein a node at an output terminal of the first emitter-follower or source-follower circuit and at an output terminal of the second emitter-follower or source-follower circuit is an output terminal of the detection circuit.

8. The Doherty amplifier circuit according to claim 1, wherein the signal indicating the drive level of the carrier amplifier is output from the first bias circuit.

9. The Doherty amplifier circuit according to claim 1, wherein the control circuit further comprises a drive level detection circuit configured to output the signal indicating the drive level of the carrier amplifier on the basis of a high frequency signal output from the carrier amplifier.

10. The Doherty amplifier circuit according to claim 1, wherein the carrier amplifier and the peak amplifier are differential amplifiers.

11. The Doherty amplifier circuit according to claim 1, further comprising:
a plurality of peak amplifiers that are connected in multiple stages; and
a plurality of second bias circuits that are configured to apply biases to the plurality of peak amplifiers,
wherein the control circuit is configured to control at least one of the plurality of second bias circuits to apply a bias to an initial-stage peak amplifier among the plurality of peak amplifiers and to control another of the plurality of second bias circuits to apply a bias to a final-stage peak amplifier among the plurality of peak amplifiers.

12. The Doherty amplifier circuit according to claim 1, further comprising:
a series resonant circuit connected between a reference potential and a node between the first bias circuit and the control circuit.

13. The Doherty amplifier circuit according to claim 1, further comprising:
a parallel resonant circuit connected between the first bias circuit and the control circuit.
